(19) United States
(12) Patent Application Publication
(10) Pub. No.: US 2026/0309805 A1
(43) Pub. Date: Oct. 8, 2026

(54) SYSTEMS AND METHODS FOR DETECTING INTERMITTENT LOOSE CONNECTION IN BATTERY ENERGY STORAGE SYSTEMS

(71) Applicant: LG Energy Solution, Ltd., Seoul (KR)

(72) Inventors: Aruna Mohan, Westborough, MA (US); Kiran Kumar, Westborough, MA (US)

(73) Assignee: LG Energy Solution, Ltd., Seoul (KR)

(21) Appl. No.: 19/640,054

(22) Filed: Apr. 6, 2026

Related U.S. Application Data
(60) Provisional application No. 63/784,849, filed on Apr. 7, 2025.

(51) Int. Cl. G01R 31/54; G01R 31/367; G01R 31/374; G01R 31/382; G01R 31/396; H02J 3/0012; H02J 3/32; H02J 103/30

(52) U.S. Cl. CPC G01R 31/54; G01R 31/367; G01R 31/374; G01R 31/382; G01R 31/396; H02J 3/0012; H02J 3/32; H02J 2103/30

(57) ABSTRACT

A method for controlling a battery energy storage system includes: receiving a current delta for each battery rack of a plurality of battery racks; determining via a machine learning model, a first battery rack of the plurality of battery racks by: comparing the current delta for each battery rack to a performance threshold, and based on the comparing, determining the first battery rack; determining, via the machine learning model, a rack deviation by determining a second difference between the mean or median current of each of the plurality of battery racks and a current of the first battery rack over a period of time, wherein the machine learning model determines the first battery rack based on current data; and initiating an action based on the rack deviation, including generating a notification, deactivating the first battery rack, or discharging the first battery rack.

### CROSS-REFERENCE TO RELATED APPLICATIONS

This application claims priority to U.S. Provisional Application No. 63/784,849, filed Apr. 7, 2025, which is hereby incorporated by reference in its entirety.

### TECHNICAL FIELD

Various embodiments of the present disclosure relate generally to battery energy storage systems, and more particularly to systems and methods for detecting intermittent loose connections in battery racks using machine learning algorithms to analyze current deviations and identify anomalous performance patterns.

### BACKGROUND

Battery Energy Storage Systems (BESS) have emerged as critical components in modern energy infrastructure. As renewable energy sources such as wind and solar power become increasingly integrated into electrical grids, their inherent intermittency creates challenges for grid stability and efficient power distribution. Beyond renewable energy applications, BESS also provides significant benefits for conventional energy generation systems by enabling load leveling, frequency regulation, and peak shaving for traditional power plants including coal, natural gas, and nuclear facilities. These systems help conventional generators operate more efficiently by reducing the need for rapid ramping, and by providing grid services that improve overall system reliability. BESS technology addresses these challenges by storing excess electricity generated during periods of low demand and releasing it during peak demand periods. This capability optimizes energy usage by reducing curtailment of renewable electricity, improving efficiency of (and reducing reliance on) fossil fuel-based power generation such as gas turbines, and supports climate change mitigation efforts by reducing greenhouse gas emissions. The importance of BESS technology continues to grow as the global energy transition accelerates and intermittent renewable sources capture larger shares of the electricity supply mix.

Commercially available batteries may include nickel-cadmium batteries, nickel-hydrogen batteries, nickel-zinc batteries, lithium, sodium-ion, lithium iron phosphate, lithium-sulfur, solid-state batteries, and the like. Among these, lithium batteries may be gaining attention due to their advantageous characteristics: they can be charged and discharged freely without memory effects, they exhibit very low self-discharge rates, and they provide high energy density compared to nickel-based alternatives. Similarly, sodium-ion batteries are emerging as promising alternatives to lithium batteries, driven by the abundance of sodium resources and their potential cost advantages.

In general, battery packs or racks typically comprise multiple cells or cell stacks arranged in series or parallel configurations. Each cell or cell stacks contains either a single battery cell or multiple battery cells connected in series. The operational state of each cell stack within the battery pack is continuously monitored by a controller equipped with a battery management system. Battery cells may be integrated directly into packs or racks, or alternatively organized into modules, with these modules then connected in series or parallel arrangements to form complete battery packs or racks. The state of each cell stack included in the battery pack may be monitored by a controller having a battery management system mounted thereon. The controller may output signals for controlling the balancing operation, cooling operation, and discharging operation based on the monitored state from each cell stack.

Conventional energy storage systems are typically configured in containerized units, where each container housing may include multiple battery racks, switchboards, HVAC systems, thermal runaway detection systems, fire suppression systems, ventilation equipment, power distribution units, monitoring sensors, safety interlocks, and other components. These containers are designed with sufficient capacity to accommodate all necessary energy storage system components within their structure. At grid scale, BESS units may be used to store reserve power to even power entire cities in the event of blackouts or other interruptions in electrical service.

Battery energy storage systems face operational challenges that can compromise performance and safety. Intermittent loose connections represent a particular concern in large-scale installations, where multiple battery racks operate in parallel configurations. These connection issues can develop gradually over time due to thermal cycling, mechanical vibration, or component degradation, leading to increased resistance and reduced current flow in affected battery racks.

Traditional monitoring approaches rely on simple threshold-based detection methods that may fail to identify subtle performance deviations until they become severe. These conventional systems typically monitor individual parameters such as voltage, current, or temperature against fixed limits, but lack the capability to analyze complex patterns or relationships between multiple battery racks operating within the same system. As a result, intermittent connection problems may go undetected during their early stages when corrective action would be most effective.

The challenge is compounded in large battery installations where hundreds or thousands of battery racks operate simultaneously across multiple geographic locations. Manual inspection and maintenance of such systems is time-consuming and may not detect intermittent issues that occur sporadically. Furthermore, the interconnected nature of battery rack systems means that performance degradation in one rack can affect the overall system efficiency and reliability. Current detection methods also struggle with distinguishing between normal operational variations and actual performance anomalies. Battery racks naturally exhibit some degree of current variation due to factors such as temperature differences, aging characteristics, and manufacturing tolerances.

The present disclosure is directed to overcoming one or more of these above-referenced challenges.

### SUMMARY OF THE DISCLOSURE

In some aspects, the techniques described herein relate to a method for controlling a battery energy storage system, the method including: receiving a current delta for each battery rack of a plurality of battery racks, wherein the current delta is a first difference in current between each battery rack and a mean or median current of the plurality of battery racks; determining, via a machine learning model, a first battery rack of the plurality of battery racks by: comparing the current delta for each battery rack of the plurality of battery racks to a performance threshold, and based on the comparing, determining the first battery rack of the plurality of battery racks; determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and initiating an action based on the rack deviation, the action including one or more of: generating a notification based on the first battery rack and the rack deviation, deactivating the first battery rack, or discharging the first battery rack.

In some aspects, the techniques described herein relate to a method, further including: determining an anomaly score scaled between 0 and 1 for the first battery rack based on the rack deviation for the first battery rack, and wherein the comparing the current delta for each battery rack of the plurality of battery racks to a performance threshold includes using a performance threshold of 0.2 to 0.4 for the scaled anomaly score.

In some aspects, the techniques described herein relate to a method, further including: receiving temperature data associated with the first battery rack; and determining the anomaly score for the first battery rack based on the rack deviation for the first battery rack and the temperature data for the first battery rack.

In some aspects, the techniques described herein relate to a method, further including: grouping the anomaly score for the first battery rack into one of a first group and a second group, based on the rack deviation for the first battery rack, wherein rack deviations of the first group are less than rack deviations of the second group; and generating the notification further includes generating the notification based on the grouping.

In some aspects, the techniques described herein relate to a method, wherein the machine learning model includes a trained machine learning model that has been trained to determine the first battery rack based on current data, and wherein the trained machine learning model includes one or more of an autoencoder model, a variational autoencoder model, or a GANomaly model, and the trained machine learning model has been trained with non-anomalous data.

In some aspects, the techniques described herein relate to a method, wherein: the trained machine learning model includes a semi-supervised machine learning algorithm trained with normal non-anomalous data, and the trained machine learning model produces an output with low reconstruction loss for non-anomalous data, and produces an output with high reconstruction loss for anomalous data to determine the first battery rack.

In some aspects, the techniques described herein relate to a method, wherein: the machine learning model includes an unsupervised machine learning algorithm, and the machine learning model is configured to cluster the current data into clustered data based on reducing within-cluster distance and separating different clusters, and applies a linkage criterion to determine the first battery rack.

In some aspects, the techniques described herein relate to a method, wherein the unsupervised machine learning algorithm includes an agglomerative hierarchical clustering model.

In some aspects, the techniques described herein relate to a method, wherein the linkage is a single linkage or a complete linkage.

In some aspects, the techniques described herein relate to a method, wherein the single linkage is used to determine a large deviation in the first battery rack, and the complete linkage is used to determine an early warning sign in the first battery rack.

In some aspects, the techniques described herein relate to a method, further including: specifying a number of clusters for the unsupervised machine learning algorithm and not specifying a number of free parameters for the unsupervised machine learning algorithm.

In some aspects, the techniques described herein relate to a method, wherein the unsupervised machine learning algorithm includes one or more of a density-based clustering model, a Gaussian mixture model, or a K-means model.

In some aspects, the techniques described herein relate to a method, wherein the machine learning model includes an encoder and a decoder.

In some aspects, the techniques described herein relate to a method, wherein the current data includes a time series of the current data as a data set of normalized values or a data set of absolute values.

In some aspects, the techniques described herein relate to a method, wherein the plurality of battery racks are located at different geographic sites, and wherein the plurality of battery racks have one or more different site configurations and one or more different operating conditions.

In some aspects, the techniques described herein relate to a non-transitory computer readable medium for controlling a battery energy storage system, the non-transitory computer readable medium storing instructions that, when executed by one or more processors, cause the one or more processors to perform operations including: receiving a current delta for each battery rack of a plurality of battery racks, wherein the current delta is a first difference in current between each battery rack and a mean or median current of the plurality of battery racks; determining, via a machine learning model, a first battery rack of the plurality of battery racks by: comparing the current delta for each battery rack of the plurality of battery racks to a performance threshold, and based on the comparing, determining the first battery rack of the plurality of battery racks; determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and initiating an action based on the rack deviation, the action including one or more of: generating a notification based on the first battery rack and the rack deviation, deactivating the first battery rack, or discharging the first battery rack.

In some aspects, the techniques described herein relate to a non-transitory computer readable medium, wherein the machine learning model includes one or more of a semi-supervised machine learning model or an unsupervised machine learning model.

In some aspects, the techniques described herein relate to a battery energy storage system including: one or more processors; and one or more memories storing instructions that, when executed by the one or more processors, cause the one or more processors to perform operations including: receiving a current delta for each battery rack of a plurality of battery racks, wherein the current delta is a first difference in current between each battery rack and a mean or median current of the plurality of battery racks; determining, via a machine learning model, a first battery rack of the plurality of battery racks by: comparing the current delta for each battery rack of the plurality of battery racks to a performance threshold, wherein the performance threshold is a scaled anomaly score from 0.2 to 0.4, and based on the comparing, determining the first battery rack of the plurality of battery racks; determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and initiating an action based on the rack deviation, the action including one or more of: generating a notification based on the first battery rack and the rack deviation, deactivating the first battery rack, or discharging the first battery rack.

In some aspects, the techniques described herein relate to a battery energy storage system, wherein the machine learning model includes one or more of a semi-supervised machine learning model or an unsupervised machine learning model.

In some aspects, the techniques described herein relate to a battery energy storage system, further including: one or more of the plurality of battery racks; and a housing for the one or more of the plurality of battery racks.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a battery, according to one or more embodiments.

FIG. 2 depicts a battery, according to one or more embodiments.

FIG. 3 depicts a controller, according to one or more embodiments.

FIG. 4 depicts a flow diagram for training a machine learning model, according to one or more embodiments.

FIG. 5 depicts a high current variation graph showing rack current delta values, according to one or more embodiments.

FIG. 6 depicts a gradual current variation graph showing rack current delta values, according to one or more embodiments.

FIG. 7 depicts a flowchart of a training process for anomaly detection using non-anomalous data, according to one or more embodiments.

FIG. 8 depicts a flowchart of an inference process for anomaly detection using site data, according to one or more embodiments.

FIG. 9 depicts a block diagram of a trained machine learning model configured as an autoencoder, according to one or more embodiments.

FIG. 10 depicts a block diagram of a trained machine learning model configured as a variational autoencoder, according to one or more embodiments.

FIG. 11 depicts a detected anomaly table showing anomalies identified by a trained machine learning model, according to one or more embodiments.

FIG. 12 depicts a mean square error graph showing reconstruction loss values, according to one or more embodiments.

FIG. 13 depicts a block diagram of a trained machine learning model configured as a GANomaly model for anomaly detection, according to one or more embodiments.

FIG. 14 depicts a scaled anomaly score graph based on original input and reconstructed data, according to one or more embodiments.

FIG. 15 depicts a reconstruction loss graph showing mean square error between original input and reconstructed input data, according to one or more embodiments.

FIG. 16 depicts a single linkage quantile graph showing step plots for rack current data analysis, according to one or more embodiments.

FIG. 17 depicts a complete linkage quantile graph showing step plots for complete linkage clustering analysis, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section.

Various embodiments of the present disclosure relate generally to battery energy storage systems, and more particularly to systems and methods for detecting intermittent loose connections in battery racks using machine learning algorithms to analyze current deviations and identify anomalous performance patterns.

Batteries may have a variety of shapes, also known as form factors. Common battery form factors include pouch-type, prismatic-type, and cylindrical-type.

Pouch-type battery cells can be produced in various lengths and widths, which may enhance the battery capacity and allow optimization of battery cells. The flexible pouch-type battery can provide significant advantages over rigid battery formats, including improved mechanical flexibility that allows the battery to conform to curved or irregular surfaces in electronic devices. This flexibility enables manufacturers to integrate pouch-type batteries into compact spaces and unconventional form factors, such as wearable devices, smartphones with curved displays, and automotive applications where space constraints require batteries to fit around other components. The lightweight and thin profile of pouch-type batteries also facilitates easier incorporation into products where weight and thickness are critical design considerations, such as tablets, laptops, and electric vehicle applications. Additionally, the pouch format allows for more efficient use of available space within a device enclosure, as the flexible packaging can be shaped to increase energy density while reducing wasted volume compared to cylindrical or prismatic battery formats.

Prismatic battery cells offer may offer advantages in applications requiring efficient space utilization and thermal management. Their rectangular form factor allows for optimal packing density within battery modules and packs, reducing wasted space and enabling higher energy density per unit volume. The flat surfaces of prismatic cells may facilitate improved heat dissipation and thermal contact with cooling systems, which can enhance overall battery performance and safety. The outer shell of prismatic cells are typically made of aluminum alloy or steel, and are typically heavier than pouch-type battery cells, making them ideal for situations where weight is a less important design consideration.

Cylindrical battery cells may provide robust mechanical strength and proven manufacturing scalability that may benefit high-volume production applications. The cylindrical geometry distributes internal pressure more evenly during charging and discharging cycles, potentially contributing to enhanced structural integrity and longer cycle life. These cells may also offer advantages in automated manufacturing processes due to their uniform shape and established production techniques, which can result in consistent quality and cost-effective mass production. Cylindrical cells are typically heavier than prismatic cells, and further have reduced energy density, as packing the batteries together typically results in gaps or spaces between the cells that are not present in pouch and prismatic form factor designs.

Modules and packs can be produced in various designs to accommodate various products. Batteries may include one or more of a tab structure, a tab-less structure, or a jelly roll design. A tab-less jelly roll design may reduce resistance while increasing power output. A zig-zag stacking design may include cross-stacking technology that alternates cathode and anode sheets with separators, enhancing both precision and safety. A Cell Array Structure (CAS) structure for batteries may increase structural rigidity, enhance cooling efficiency, and ensure superior safety.

The assembly of the "cylindrical battery", the most commonly encountered battery form in our daily life, starts with "winding". Winding is a process where a machine called a winder rolls up the cathode and anode electrodes. This process has the advantage of being very fast, similar to how a "tissue roll" can quickly wrap the paper around the tissue core. During winding, cathode, anode, and separator rolls are unwound, and an aluminum tab is attached to the cathode's blank part while a copper tab is attached to the anode's blank part. Then they are attached to the winder in the order of cathodeseparator-anode-separator, wound around a mandrel, like rolling toilet paper around its core, and then cut into an appropriate size to form a jelly roll.

Once the jelly roll is formed, it goes through various assembly processes to take the form of the familiar cylindrical battery. At first, the jelly roll produced by the winding method is inserted into a can so that the anode touches its bottom and the anode tab is bent at a 90-degree angle to make contact with the anode. After inserting the jelly roll into the can, it is attached using a resistance welding method. Resistance welding is also known as "spot welding" because bead-like spots are created when the metal melts and solidifies. After welding, a process called "beading" is used to create the neck of the cell, allowing the top cap to be fitted later.

Once the cylindrical shape of the battery is completed through beading, electrolyte is injected. To do this, a vacuum is created inside of the can and the electrolyte is injected into it through a nozzle. Then, the can is pressed to let the electrolyte fill the pores of the electrode. Once the electrolyte injection is complete, the cathode tab and the top cap are attached to the cell using laser welding. Finally, the cylindrical battery is completed by mechanically sealing it through the crimping and sizing processes, producing it to standardized dimensions. After the assembly process is completed, the battery undergoes cleaning, quality verification, and formation processes before being delivered to the customers.

Pouch-type batteries may be manufactured differently from cylindrical batteries. To place battery materials into the electrode pocket of a pouch case, a mono-cell is required. A mono-cell is the basic unit of a battery, consisting of a cathode, an anode, and two separators arranged in a layered structure, such as "separator - central electrode - separator - external electrode." The lamination and stacking processes are applied to this mono-cell. To be more specific, the process begins with lamination, a method for aligning and bonding the cathode, anode, and separator. This is followed by stacking, during which monocells are repeatedly layered. Finally, stacking half-cells - each made up of two separators and an anode - forms a cell stack, where the cathode and anode are alternately layered with separators in between. Lamination & stacking technology increases space efficiency within the pouch case, further enhancing energy density. Stacking, which involves individually layering battery cells, requires advanced technical expertise. By applying lamination & stacking, misalignment between cells is reduced, and empty spaces within the battery cell are eliminated, resulting in higher energy density. Lamination & stacking technology with mono-cells may be used to produce a range of pouch-type batteries, from ultra-thin batteries under 2mm to long cells.

The cell stack, produced through lamination and stacking, then moves to the packaging stage. First, leads are welded onto the cell stack, which comprises multiple layers of mono-cells. Next, a pouch film is compressed to form a pocket, and the lead-welded cell stack is inserted into this pouch pocket for assembly. To seal the pocket, heat and pressure are applied using a sealing tool.

During this process, two pockets are formed: the electrode pocket and the gas pocket. The electrode pocket houses the cell stack, including the cathode, anode, separator, and electrolyte. The gas pocket, meanwhile, serves as an entry for electrolyte injection and as a space to store gases generated during the injection process. After injecting the electrolyte into the gas pocket, the injection port is sealed with the sealing tool, completing the assembly of the pouchtype battery. In the following formation process, any unwanted gases that are generated and accumulated in the gas pocket are removed during the degassing stage by trimming the gas pocket.

Prismatic battery cell manufacturing may share some similarities with cylindrical cell production, while incorporating unique processes tailored to the rectangular form factor. The manufacturing process typically begins with electrode preparation, where cathode and anode materials are coated onto current collectors, similar to other battery types. However, prismatic cells may utilize either a winding process similar to cylindrical cells or a stacking process similar to pouch cells, depending on the specific design requirements and manufacturer preferences. The electrode assembly is then inserted into a rigid metal casing, which may be made of aluminum alloy or steel, providing structural integrity that differs from the flexible pouch format.

The assembly and sealing processes for prismatic cells may involve specialized techniques that accommodate the rectangular geometry and rigid housing. Electrolyte injection in prismatic cells may require precise control to ensure uniform distribution throughout the rectangular cell structure, which can be more challenging than the cylindrical geometry due to potential dead zones in corners. The sealing process typically involves laser welding or mechanical crimping of the metal casing, providing a hermetic seal that may offer enhanced safety compared to pouch cells but requires more complex manufacturing equipment than cylindrical cells. Quality control and formation processes for prismatic cells may need to account for the unique thermal and electrical characteristics of the rectangular form factor, potentially requiring different testing protocols compared to cylindrical or pouch cell manufacturing.

After completion of the formation and acquiring electrical characteristics, batteries are either delivered as individual cells or modularized to suit (or fit) electric vehicle models. The pack process involves modularizing the battery cells and placing them into packs before final delivery.

The first step in the pack process is to bundle battery cells to build a module. First, several surfacecleaned battery cells are arranged in a "cell to cell" configuration, which are retained into a module case with adhesives. Then bus bars and leads are welded to connect to the cells with a laser welder, and the module build is completed with installing module top cover. Finally, a pack build is completed when these modules are placed into the battery pack enclosures and connected to each other. These complete battery packs are then installed in many applications such as electric vehicles and various IT devices. The number of cells and modules in a battery pack may vary, depending on the battery cells and application models.

Because a battery pack contains multiple cells or modules, balancing and managing these cells is critical, especially to accurately measure state of charge and optimize battery life. Therefore, once a pack is assembled, the battery is monitored, and its performance maintained in optimal conditions using a control system called BMS (Battery Management System), which estimates the battery's charging state and life. The CMS (Cell Monitoring System) inside the BMS measures the cells' condition and performs balancing to ensure optimal battery performance, safety, and life.

"Cell balancing" refers to adjusting the voltage differences between two or more serially connected cells. For instance, if two cells connected in series reach voltages of 4.2V and 4.0V, respectively, during charging, cell balancing adjusts this 0.2v difference to equalize the voltage. Voltage imbalance can occur due to manufacturing or external factors, and it can affect battery capacity and life, posing risks of overcharging, over-discharging, and fire hazards. Hence, cell balancing is essential.

Mobility and IT battery products have a wide variety of applications in IT devices such as smartphones and laptops, as well as LEVs (Light Electric Vehicles), electric bicycles, power tools, and wireless earphones. In general, energy is difficult to store and is lost after being used. Energy Storage Systems (ESS) are systems that store and manage energy so the energy can be used more efficiently. ESS has applications in power plants, power transmission and distribution facilities, homes, factories, and businesses. Through a system that is coupled with renewable energy, ESS can increase the efficiency of renewable energy and reduce electricity costs. ESS can also be used as backup power to reduce damages from power outages.

For example, solar modules installed on the roof of homes and ESS for uninterruptible power supply (UPS) in data centers store power and use the stored power during times of high demand or when electricity prices are high. In turn, ESS reduces damages from blackouts and saves electricity bills. Also, power plants can store and manage irregularly produced renewable energy, such as solar, wind, and hydroelectric power, which increases the efficiency of their use.

When used in conjunction with solar panel installations at home, ESS stores electricity produced by solar panels during daytime to be used at nighttime. A home battery may be a solution that can serve as an alternative energy source to reduce electricity costs and prepare for power outages. Installing ESS and solar power systems together generates power independently, increasing the self-consumption of power at home and reducing the overall electricity cost.

ESS for power grids, also commonly referred to as BESS, may be installed proximate to thermal power plants, solar and wind power plants, and substations. ESS for power grids has various applications in reducing power load, coupling with renewable power generation, and adjusting power frequency. Commercial ESS installed in commercial buildings such as offices, schools, factories, data centers, and the like may be used to reduce power load, or may be coupled with renewable power generation. ESS may include backup power solutions that protect facilities that require the constant supply of power, such as data centers and IT/telecommunications facilities. ESS may also be used to enable participation in an optimized energy marketplace, where excess power is sold back to the grid during peak hours and charged during off-peak hours. While BESS is ideal for use with renewable energy systems, BESS can store energy from many different sources, including energy generated by fossil fuels, hydropower, or any other power source that generates usable electricity.

An ESS is a system that stores electricity produced and supplies it when needed, thereby enhancing energy efficiency. It mainly includes four components: a battery, a power conversion system (PCS), a battery management system (BMS), and an energy management system (EMS). The PCS is a power conversion device that converts alternating current to direct current and vice versa. The BMS is a battery management system that typically monitors and/or controls one or more battery cells, packs, racks, and/or modules in the ESS, and includes safety features that stop charging and discharging if abnormalities in voltage, current, or temperature are detected. The EMS is a system that monitors the amount of electricity stored in the ESS and serves as a software responsible for the overall operation of the ESS.

There are three primary roles of ESS. First, it acts as an uninterrupted power supply in places where power outages must be avoided at all costs, such as hospitals and banks. In cases of power outages caused by typhoons or fires, it assists in power supply to prepare for large-scale blackout situations. Second, it stores generated energy and supplies it during peak power demand times. It helps to stabilize energy output by compensating for the inconsistent generation levels of new renewable energies such as solar and wind power. In homes, it can save on electricity bills by storing electricity during cheaper hours and using it during more expensive daytime hours. Third, it maintains the standard power frequency at 60 Hz in the power supply system, countering frequency fluctuations due to mismatches in supply and demand, thereby enhancing power quality.

A battery system may include controlling power to and from batteries and providing control signals. A battery energy storage system (BESS) may include a battery management system (BMS), a local energy management system (EMS), external data reporting, a power plant controller, a utility EMS, and fleet-level controls. The BMS may collect inputs from battery cells and modules, and may operate individual cells or groups of cells. The BMS may include a controller. The BMS may balance voltages in the battery cells, for example. The local EMS may collect information from the BMS, and may control the operations of the BMS at a system level. The EMS may determine available power and capacity of the BESS, for example. External data reporting may include components such as transformers, switchgear, or meters. The power plant controller may coordinate the local EMS with a supervisory system. The utility EMS may control an electrical grid connected to the BESS. The fleet-level controls may coordinate to operate multiple BESS’s at different locations. Communications between these components may be established wirelessly or through connected wires, depending on the system configuration and operational requirements.

BMS is a management system to monitor and control the status of batteries to operate them under optimal conditions. It measures the current, voltage, and temperature of batteries in Battery Electric Vehicles (BEVs) or Energy Storage Systems (ESS) with sensors, and identifies and controls potential concerns so that the batteries can maintain the highest performance possible. The location of the BMS can vary depending on the battery type or product.

The battery system includes the cell as the smallest unit, the module of a group of cells, and the pack of the final form of the battery. The role of BMS in a battery can be compared to that of a choir conductor. As a conductor sets the tone and tempo to combine different voices of the choir into a harmonious song, BMS tunes the current and voltage of each cell like a conductor.

BMS performs three main functions: monitoring, cell management, and control. Monitoring involves observing voltage, current, temperature, etc., through sensors in the battery system, and predicting state of charge (SoC) and the state of health (SoH) of the battery based on the data. Cell management refers to cell balancing, which reduces the voltage differences between battery cells to enhance energy efficiency and charging rate. Control is the process of regulating to prevent overcharging, overdischarging, and overcurrent in the battery. Ultimately, BMS plays a role in managing the life, performance, and safety of the battery, and as batteries continue to develop, BMS is also becoming more sophisticated and continues to evolve.

"C-rate" is a term one needs to know when dealing with fast charging speeds to the extent of acquiring special chargers and cables capable of rapid charging. Abbreviated from "current rate", the C-rate is a measure of the rate at which a battery is charged or discharged. It is also called "charge and discharge rates" and uses "C" as the unit, which is the abbreviation of "capacity". C-rate can be calculated by dividing the charging or discharging current (A) by the rated battery capacity (Ah). The standard C-rate is generally 1C.

Understanding the C-rate is very helpful when using batteries. First, the charge C-rates help users estimate how long it will take to fully charge their batteries. For example, when one sees a battery label that states, "Chargeable at 10C," it means the battery can be charged at a current of 10 times the battery capacity, and it takes at least 6 minutes to be completely charged.

On the other hand, the discharge C-rates help users predict the limits of product performance. For instance, a drone battery with a high discharge C-rate indicates a faster discharge rate, meaning it can perform complex maneuvers that require sudden high currents. Conversely, a low discharge C-rate could mean difficulty in performing high-performance actions that require high currents. Let us suppose that there is a drone battery with a discharge C-rate of 100C. The battery can supply a current of up to 100 times its capacity, but if the drone continues the move that requires that much power, it is discharged 100 times faster than the standard of an hour (3,600 seconds). Accordingly, it is discharged in just 36 seconds. As the use of batteries in our daily lives increases, and more products require fast charging or a sudden rush of high current, understanding the concept of C-rate will help us choose the right battery for each electronic device.

When we use portable electronic devices, we always check the battery's charge status. For instance, the battery icon on a phone shows percentages like 100%, 50%, 20%, etc. This indicator, showing how much percentage of the battery is left, is known as "SoC". Soc stands for "State of Charge". It represents the remaining battery capacity in percentage (%) which is the current usable battery capacity divided by the total capacity.

Accurate SoC measurement is a core competitive aspect for battery manufacturers. As such, there are various methods to measure SoC, including chemical, voltage, current integration, and pressure measurement methods. SoC is an element to provide convenience to users. Through SoC measurements, it is possible to determine how much longer the battery can be used more and users can determine when to charge and end the battery themselves, allowing them to use the device more efficiently. From the manufacturer's perspective, SoC is considered very important as it can enhance the stability of the battery. By setting the maximum charge of the battery lower than the highest point of the SoC and the minimum charge of the battery higher than the lowest point of the SoC, various problems such as safety issues due to overcharging and over-discharging of the battery can be prevented in advance. As a result, a more stable battery usage environment can be provided to users.

Batteries, like all other products, have a lifespan. The SoH (State of Health) is a useful indicator for the remaining life and the current state of batteries. It shows the battery's condition compared to its initial conditions at a glance. One can easily check the SoH on some smartphones, tablets, or laptops. Devices that do not provide SoH information, such as "maximum battery performance", can be assessed through specialized testing equipment. However, SoHs can vary even among batteries that have been used for the same period because battery life is affected by many factors, including user habits and the environment. In particular, if the electric vehicle battery is well managed, it is possible to drive the vehicle for 2 to 3 times longer than the manufacturer's warranty period with little decrease in SoH. SoH is referred to as "Maximum capacity" on some devices.

Recently, with many second-hand transactions taking place in real life, transactions of IT devices with batteries, such as smartphones and tablet PCs, are also increasing. At this time, SoH is a factor that must be checked to trade better products. Not only a second-hand transaction, but also an IT device with a built-in battery can be used more efficiently if the health status of the battery is checked with the SoH.

A cell is the basic unit of a battery. In devices requiring a lot of power, like electric vehicles, a battery pack contains numerous cells. However, even identical cells may develop voltage differences due to manufacturing processes or external factors. For example, when two cells connected in series are charged, the first cell could reach 4.2 V while the second cell stops at 4.0 V. Such imbalances between cells can affect battery capacity and life, and significantly increase the risk of safety issues due to overcharging and over-discharging. To prevent this, "cell balancing" is necessary.

Cell balancing adjusts and aligns the voltage differences between serially connected battery cells. It can be of two types: passive and active. Passive cell balancing dissipates the charging energy of a cell through a resistance to lower the cell voltage. In other words, it removes the charge from cells with more capacity by dissipating heat, making the charge of all cells uniform. While this method is simple and costeffective, it is less energy-efficient as it wastes excess voltage and can only be applied during charging.

Active cell balancing transfers the charging energy from cells with higher voltage to those with lower voltage. It redistributes the charge to equalize the voltage between cells by providing more capacity to cells with less capacity. Unlike passive cell balancing, which dissipates heat, active balancing redistributes energy, making it more energy-efficient and faster in charging. While active cell balancing can be applied during both charging and discharging, it involves more complex additional circuitry and is thus more costly. Cell balancing happens in the BMS (Battery Management System), where the CMU (Cell Monitoring Unit) in the BMS measures the state of the cells and starts balancing, enabling safer use of the battery.

One or more embodiments may relate to IRC (Intermittent Loose Connection) detection in battery energy storage systems. IRC may lead to higher resistance and lower rack current relative to normal racks. One or more embodiments may provide a model to analyze rack current data and flag anomalous racks with underperforming currents. However, there may be only limited known cases of IRC, such as those observed at specific battery installations. It may not be possible to train a robust machine learning model based on supervised learning with only a few positive cases. Instead, one or more embodiments may use unsupervised learning through clustering or semisupervised learning through generative models to identify underperforming racks as anomalous relative to other racks.

Rack currents may generally vary with operational power profiles over time. One or more embodiments may focus on underperforming racks, which may be identified from the distribution of rack current deviations relative to the mean current of all racks in the battery zone. For each rack, one or more embodiments may calculate current delta for underperforming racks only, which may be determined as the mean current of all other racks minus the rack current for 30-second intervals over a 1-day period. Features may be statistical metrics of the resulting distribution of underperforming rack current deltas, including quantiles, standard deviation, interquartile range, and spreads. Temperature-based features may not be included in this model, as these may lead to multimodal distributions. Instead, temperature may be used as a separate screening criterion after the machine learning model. One or more embodiments may include application of the clustering and generative modeling approaches to time series data directly, and normalized time series data instead of absolute values of current.

Data may be collected from multiple battery installation sites for selected days, potentially comprising thousands of data points. The anomalous racks may show much bigger current deviations than normal racks. To avoid rule-based systems, this identification may be automated by unsupervised or semisupervised machine learning methods. Some installations may clearly show racks with much higher current delta values, while other installations may show more gradual variation between racks.

One or more embodiments may utilize semisupervised learning with generative artificial intelligence. The training process may use only normal, non-anomalous data, where the generative model may learn to reconstruct normal data with low reconstruction loss. The training process may not use anomalous data and may work for highly unbalanced data. During inference, the model input may include normal non-anomalous and anomalous data, but the model may fail to reconstruct anomalous data. Anomalous data may be identified by high reconstruction loss. Generative models may include autoencoder, variational autoencoder, and GANomaly, for example.

Model training may use normal, non-anomalous rack data from multiple sites, which may require selection of normal data excluding any known IRC data for training. The deployed model during inference may be fed daily rack data from multiple sites, which may include normal and potentially anomalous data from multiple sites and racks.

An autoencoder may implement a bottleneck to learn a reduced representation of the data. The encoder may compress input data into a lower-dimensional code representation, while the decoder may reconstruct the data from the reduced representation. The system may reduce reconstruction loss while training the encoder-decoder model. For anomaly detection, normal data may be used in the training process, so the autoencoder model may learn how to reconstruct normal data. During inference, when the trained model may be provided anomalous data, reconstruction loss may be high. Anomalous data may be identified from high reconstruction loss.

A beta-variational autoencoder (β-VAE) may provide reconstruction loss analysis. Anomalous points may be identified by setting a threshold on reconstruction mean square error (MSE) loss. This may require subjective judgment for setting the threshold, though known anomalous cases may be used as a comparison. The β-VAE may identify anomalous datapoints, which may correspond to known problematic installations and specific battery racks during particular time periods.

GANomaly may be based on a generator with encoder-decoder-encoder structure and a discriminator. In one or more embodiments, deep neural network (DNN) architecture may be used, but convolutional neural network (DCGAN) architecture may be used for time series data. GANomaly may provide scaled anomaly scores and reconstruction loss. By thresholding these scores, anomalous points and early warning signs may be identified. Reconstruction loss may be based on the difference between original and reconstructed input data, while the scaled anomaly score may be based on scaling the reconstruction loss on the test dataset to lie between 0 and 1.

In all of the above cases (autoencoder, variational autoencoder, or GANomaly), a scaled anomaly score may be defined on the test dataset, which includes normal and anomalous data, by scaling the reconstruction loss between the original and reconstructed data to lie between 0 and 1.

Generative modeling may provide several benefits. The models may provide a scaled anomaly score from 0 to 1, so the user may decide where to set the threshold. Early warning windows may be flagged. The models may require only normal non-anomalous data for training through a semi-supervised approach, making them suitable for very unbalanced datasets with very few true positives. The approach may be valuable for anomaly detection based on large amounts of current, voltage, and temperature time series data. However, there may be downsides, including subjective judgement required for selecting thresholds on the anomaly scores. In practice, known anomalous cases may be used for comparison to set the threshold. The models may need to train on a large set of normal observations to accurately identify anomalous data deviating from normal observations.

One or more embodiments may utilize clustering methods for unsupervised learning, where there may be no labeled dataset. Clustering algorithms may assign points to clusters based on minimizing within-cluster distance and separating different clusters. Agglomerative hierarchical clustering may form a specified number of clusters by clustering points based on linkage criteria, including single linkage using minimum distance criteria and complete linkage using maximum distance criteria. Other clustering methods may be used. DBSCAN may provide density-based clustering but may require adjustable distance parameters. Gaussian Mixture Model may cluster points into a specified number of Gaussian clusters. K-Means may be suitable for spherical clusters.

Agglomerative hierarchical clustering results may show that single linkage may identify only large deviations, while complete linkage may identify smaller gradual deviations, which may serve as an early warning sign. The clustering approach may provide benefits including no requirement for a labeled dataset, making unsupervised learning suitable for very unbalanced datasets containing very few true positives. The method may need only to specify the number of clusters to be found, with no free parameters in this implementation of agglomerative hierarchical clustering. However, clustering may not provide an anomaly score and may provide only cluster assignment.

One or more embodiments may provide generative models such as autoencoder, β-VAE, and GANomaly that work well for anomaly detection. These models may provide an anomaly score, which may be used as an early warning sign. There may be subjective judgement involved in setting the threshold for identifying anomalies, though in practice, known anomalous cases may be used for comparison. Agglomerative hierarchical clustering may also work well for identifying anomalies and may not have adjustable parameters. This approach may provide only a cluster assignment, not an anomaly score. These methods may work with unbalanced datasets containing very few true positives. The methods may be applicable more generally to anomaly detection for current, voltage, and temperature time series data. These methods may be applied directly to time series current data. The time series data for currents may be normalized, instead of using absolute values, before applying these methods.

One or more embodiments may include machine learning algorithms for detecting intermittent loose connections in battery racks. The machine learning algorithms may provide an improvement in the functioning of the hardware performance of battery energy storage systems by automatically identifying underperforming battery racks before complete failure occurs, thereby preventing cascading failures across multiple battery racks and reducing mechanical stress on electrical connections. The early detection capability may extend the operational lifetime of battery rack hardware by enabling proactive maintenance interventions that address connection degradation before it progresses to complete disconnection or thermal damage.

One or more embodiments may include generative machine learning models trained on normal operational data. The generative machine learning models may provide an improvement in technology by reducing computational overhead on battery management system controllers through semi-supervised learning approaches that require only normal data for training, thereby eliminating the need for extensive labeled datasets of anomalous conditions and reducing memory storage requirements for training data.

One or more embodiments may include unsupervised clustering algorithms for anomaly detection. The unsupervised clustering algorithms may provide an improvement in the functioning of the hardware performance of battery monitoring systems by enabling real-time analysis of current deviations across multiple battery racks without requiring manual threshold setting, thereby reducing false positive alerts that can cause unnecessary hardware shutdowns and improving the reliability of automated safety systems.

One or more embodiments may include statistical analysis of current delta measurements over ten to thirty second intervals. The statistical analysis may provide an improvement in technology by enhancing the accuracy of intermittent loose connection detection through continuous monitoring of current deviations relative to mean rack performance, thereby enabling detection of gradual performance degradation that traditional threshold-based systems would miss until severe hardware damage occurs.

One or more embodiments may include autoencoder and variational autoencoder architectures for reconstruction loss analysis. The autoencoder and variational autoencoder architectures may provide an improvement in the functioning of the hardware performance of battery energy storage systems by providing scaled anomaly scores that enable early warning detection of connection issues, thereby allowing maintenance teams to address hardware problems during scheduled maintenance windows rather than during emergency shutdowns that can stress other system components.

One or more embodiments may include agglomerative hierarchical clustering with single and complete linkage criteria. The agglomerative hierarchical clustering may provide an improvement in technology by automatically distinguishing between large current deviations requiring immediate hardware intervention and smaller gradual deviations that serve as early warning indicators, thereby optimizing maintenance scheduling and reducing unnecessary hardware replacements while preventing catastrophic failures.

One or more embodiments may include time series analysis of normalized current data across multiple geographic battery installation sites. The time series analysis may provide an improvement in the functioning of the hardware performance of distributed battery energy storage systems by enabling centralized monitoring and predictive maintenance across multiple installations, thereby reducing the need for on-site diagnostic equipment at each location and improving overall system reliability through pattern recognition across diverse operating conditions.

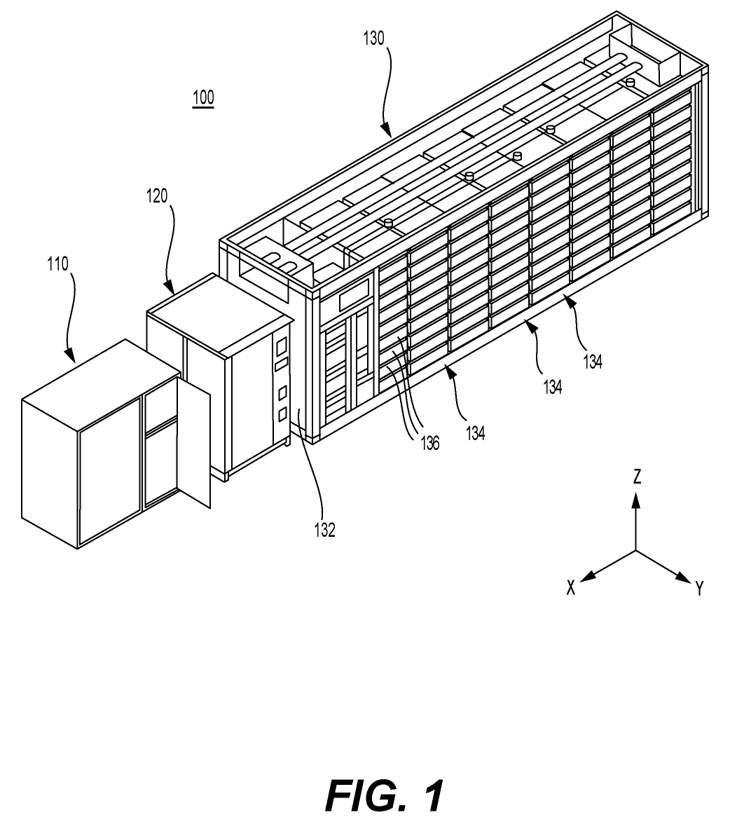

FIG. 1 depicts an exemplary battery system infrastructure, according to one or more embodiments. Battery energy storage system 100 may include battery control 110, battery thermal protection 120, and battery array 130. Battery array 130 may include housing 132 and battery rack 134 (e.g., one or more battery racks, eight battery racks).

Housing 132 may be a battery frame, for example. Battery rack 134 may include battery module 136 (e.g., one or more battery modules, nine battery modules). Battery module 136 may include one or more battery cells in a module case. Battery module 136 may be stacked in a direction, for example, in a vertical direction as battery rack 134. Battery rack 134 may include a rack case to facilitate stacking the battery module 136. Each battery module 136 may be received in a receiving space of the rack case as a module stack. One module stack may constitute one of battery rack 134. Alternatively, two or more module stacks may constitute one of battery rack 134.

Battery module 136 included in the battery rack 134 may further include a control unit such as a battery management system (BMS) for each battery module or each predetermined group. For example, each battery module 136 may include a pack BMS. A battery module 136 including a pack BMS may be referred to as a battery pack. For example, the battery rack 134 may include a plurality of battery packs. Alternatively, a battery pack assembly may include one or more battery cells with a module-less design, such as a direct cell-to-pack design, for example.

The battery rack 134 may be arranged in at least one direction, for example, a horizontal direction. For example, battery array 130 may include eight battery racks of battery rack 134 that may be arranged in the left-right direction (X-axis direction) in battery array 130. Each battery rack 134 may have a control unit, for example, a rack BMS. The rack BMS may be connected to the plurality of pack BMSs included in battery rack 134 to transmit and receive data to and from the plurality of pack BMSs and control them.

The rack BMS may be connected to a control device, for example, battery control 110. Battery rack 134 may include an integrated control unit such as, for example, a battery processing unit (BPU) which may perform communications or control operations with the plurality of rack BMSs.

Housing 132 may be a container housing. Housing 132 may have an empty internal space. Housing 132 may accommodate the battery rack 134 in the internal space. More specifically, as depicted in FIG. 1, housing 132 may be formed in the shape of an approximately rectangular prism. Housing 132 may include an upper housing, a lower housing, a front housing, a rear housing, a left housing, and a right housing with respect to the internal space. Housing 132 may accommodate the battery rack 134 in the internal space defined by these six unit housings.

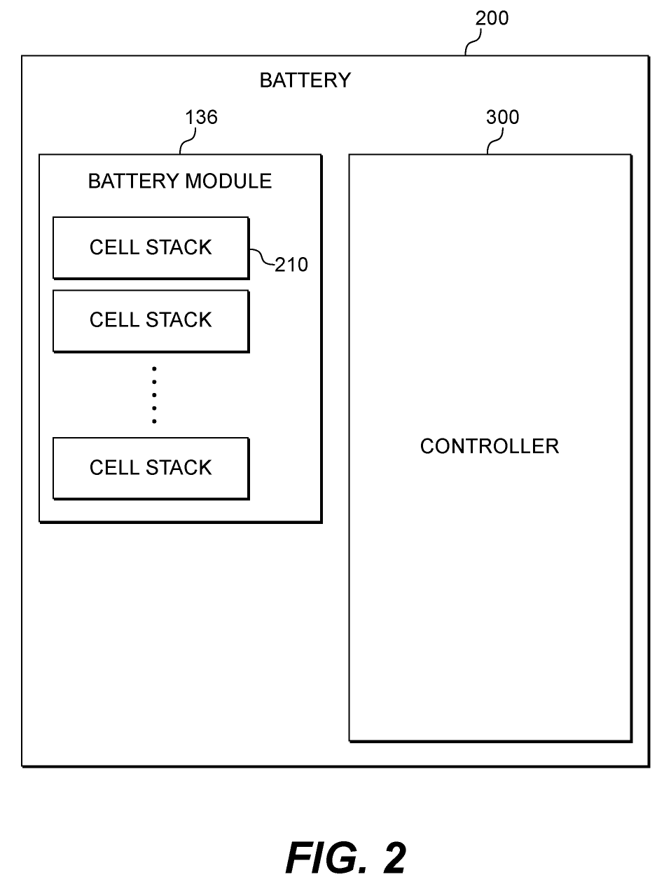

FIG. 2 depicts a battery, according to one or more embodiments. Battery 200 may include a battery module 136 and controller 300. Battery module 136 may include a plurality of cell stacks, including cell stack 210.

Battery 200 may include a battery pack. Battery 200 may include an overcharge prevention apparatus. Overcharge prevention apparatus may include a voltage measuring unit, a current regulating unit, a controller 300, and optionally may further include at least one of a disconnecting unit, a current measuring unit, and a cooling unit. Additionally, when the overcharge prevention apparatus includes a disconnecting unit, a discharge inducing unit may be included.

The plurality of cell stacks, which may include cell stack 210, may be connected in series and installed on a high current path between two power terminals of battery 200. A voltage measuring unit may measure the voltage of each cell stack 210, and may generate a first monitoring signal indicating the measured voltage. The first monitoring signal generated by the voltage measuring unit may be transmitted to the controller. The current regulating unit may be configured to selectively provide each cell stack 210 with bypass paths connected in parallel. Current regulating unit may provide bypass paths individually to the plurality of cell stacks, which may include for example cell stack 210.

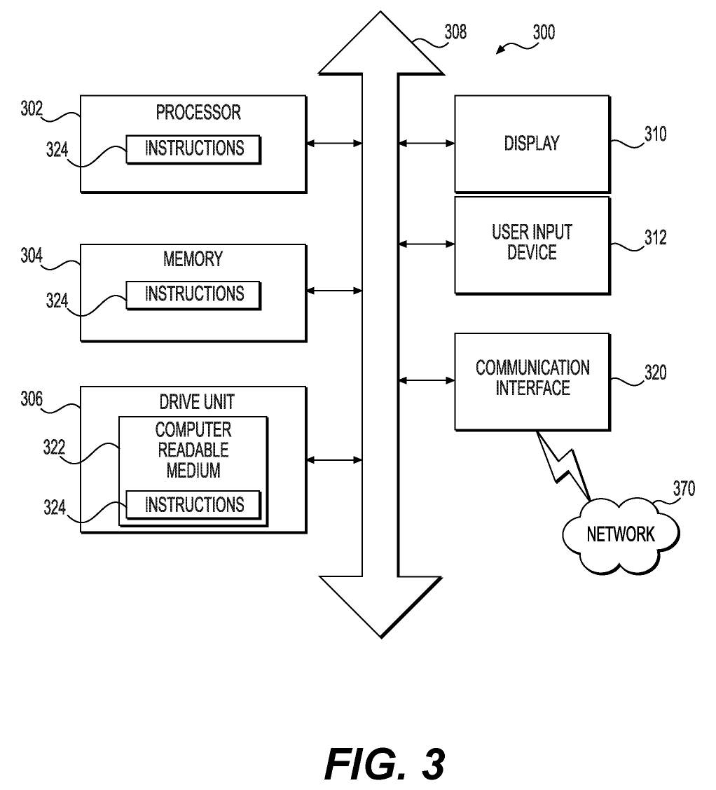

FIG. 3 depicts a controller, according to one or more embodiments. FIG. 3 and the following discussion provide a brief, general description of a suitable computing environment in which the present disclosure may be implemented. In one embodiment, any of the disclosed systems, methods, and/or graphical user interfaces may be executed by or implemented by a computing system consistent with or similar to that depicted in FIG. 3. Although not required, aspects of the present disclosure are described in the context of computer-executable instructions, such as routines executed by a data processing device, e.g., a server computer, wireless device, and/or personal computer. Those skilled in the relevant art will appreciate that aspects of the present disclosure can be practiced with other communications, data processing, or computer system configurations, including: Internet appliances, hand-held devices (including personal digital assistants (“PDAs”)), wearable computers, all manner of cellular or mobile phones (including Voice over IP (“VoIP”) phones), dumb terminals, media players, gaming devices, virtual reality devices, multi-processor systems, microprocessor-based or programmable consumer electronics, set-top boxes, network PCs, mini-computers, mainframe computers, and the like. Indeed, the terms “computer,” “server,” and the like, are generally used interchangeably herein, and refer to any of the above devices and systems, as well as any data processor.

Aspects of the present disclosure may be embodied in a special purpose computer and/or data processor that is specifically programmed, configured, and/or constructed to perform one or more of the computer-executable instructions explained in detail herein. While aspects of the present disclosure, such as certain functions, are described as being performed exclusively on a single device, the present disclosure may also be practiced in distributed environments where functions or modules are shared among disparate processing devices, which are linked through a communications network, such as a Local Area Network (“LAN”), Wide Area Network (“WAN”), and/or the Internet. Similarly, techniques presented herein as involving multiple devices may be implemented in a single device. In a distributed computing environment, program modules may be located in both local and/or remote memory storage devices.

Aspects of the present disclosure may be stored and/or distributed on non-transitory computer-readable media, including magnetically or optically readable computer discs, hard-wired or preprogrammed chips (e.g., EEPROM semiconductor chips), nanotechnology memory, biological memory, or other data storage media. Alternatively, computer implemented instructions, data structures, screen displays, and other data under aspects of the present disclosure may be distributed over the Internet and/or over other networks (including wireless networks), on a propagated signal on a propagation medium (e.g., an electromagnetic wave(s), a sound wave, etc.) over a period of time, and/or they may be provided on any analog or digital network (packet switched, circuit switched, or other scheme).

The controller 300 may include a set of instructions that can be executed to cause the controller 300 to perform any one or more of the methods or computer-based functions disclosed herein. The controller 300 may operate as a standalone device or may be connected, e.g., using a network, to other computer systems or peripheral devices.

In a networked deployment, the controller 300 may operate in the capacity of a server or as a client in a server-client user network environment, or as a peer computer system in a peer-to-peer (or distributed) network environment. The controller 300 can also be implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the controller 300 can be implemented using electronic devices that provide voice, video, or data communication. Further, while the controller 300 is illustrated as a single system, the term “system” shall also be taken to include any collection of systems or sub-systems that individually or jointly execute a set, or multiple sets, of instructions to perform one or more computer functions.

As illustrated in FIG. 3, the controller 300 may include a processor 302, e.g., a central processing unit (CPU), a graphics processing unit (GPU), or both. The processor 302 may be a component in a variety of systems. For example, the processor 302 may be part of a standard computer. The processor 302 may be one or more general processors, digital signal processors, application specific integrated circuits, field programmable gate arrays, servers, networks, digital circuits, analog circuits, combinations thereof, or other now known or later developed devices for analyzing and processing data. The processor 302 may implement a software program, such as code generated manually (i.e., programmed).

The controller 300 may include a memory 304 that can communicate via a bus 308. The memory 304 may be a main memory, a static memory, or a dynamic memory. The memory 304 may include, but is not limited to computer readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media, and the like. In one implementation, the memory 304 includes a cache or random-access memory for the processor 302. In alternative implementations, the memory 304 is separate from the processor 302, such as a cache memory of a processor, the system memory, or other memory. The memory 304 may be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 304 is operable to store instructions executable by the processor 302. The functions, acts or tasks illustrated in the figures or described herein may be performed by the processor 302 executing the instructions stored in the memory 304. The functions, acts or tasks are independent of the particular type of instructions set, storage media, processor or processing strategy and may be performed by software, hardware, integrated circuits, firm-ware, micro-code, and the like, operating alone or in combination. Likewise, processing strategies may include multiprocessing, multitasking, parallel processing, and the like.

As shown, the controller 300 may further include a display 310, such as a liquid crystal display (LCD), an organic light emitting diode (OLED), a flat panel display, a solid-state display, a cathode ray tube (CRT), a projector, a printer or other now known or later developed display device for outputting determined information. The display 310 may act as an interface for the user to see the functioning of the processor 302, or specifically as an interface with the software stored in the memory 304 or in the drive unit 306.

Additionally or alternatively, the controller 300 may include an input device 312 configured to allow a user to interact with any of the components of controller 300. The input device 312 may be a number pad, a keyboard, or a cursor control device, such as a mouse, or a joystick, touch screen display, remote control, or any other device operative to interact with the controller 300.

The controller 300 may also or alternatively include drive unit 306 implemented as a disk or optical drive. The drive unit 306 may include a computer-readable medium 322 in which one or more sets of the instructions 324, e.g., software, can be embedded. Further, the instructions 324 may embody one or more of the methods or logic as described herein. The instructions 324 may reside completely or partially within the memory 304 and/or within the processor 302 during execution by the controller 300. The memory 304 and the processor 302 also may include computer-readable media as discussed above.

In some systems, a computer-readable medium 322 includes instructions 324 or receives and executes instructions 324 responsive to a propagated signal so that a device connected to a network 370 can communicate voice, video, audio, images, or any other data over the network 370. Further, the instructions 324 may be transmitted or received over the network 370 via a communication port or interface 320, and/or using a bus 308. The communication port or interface 320 may be a part of the processor 302 or may be a separate component. The communication port or interface 320 may be created in software or may be a physical connection in hardware. The communication port or interface 320 may be configured to connect with a network 370, external media, the display 310, or any other components in controller 300, or combinations thereof. The connection with the network 370 may be a physical connection, such as a wired Ethernet connection or may be established wirelessly as discussed below. Likewise, the additional connections with other components of the controller 300 may be physical connections or may be established wirelessly. The network 370 may alternatively be directly connected to a bus 308.

While the computer-readable medium 322 is shown to be a single medium, the term "computer-readable medium" may include a single medium or multiple media, such as a centralized or distributed database, and/or associated caches and servers that store one or more sets of instructions. The term "computer-readable medium" may also include any medium that is capable of storing, encoding, or carrying a set of instructions for execution by a processor or that cause a computer system to perform any one or more of the methods or operations disclosed herein. The computer-readable medium 322 may be non-transitory, and may be tangible.

The computer-readable medium 322 can include a solid-state memory such as a memory card or other package that houses one or more non-volatile read-only memories. The computer-readable medium 322 can be a random-access memory or other volatile re-writable memory. Additionally or alternatively, the computer-readable medium 322 can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative implementation, dedicated hardware implementations, such as application specific integrated circuits, programmable logic arrays and other hardware devices, can be constructed to implement one or more of the methods described herein. Applications that may include the apparatus and systems of various implementations can broadly include a variety of electronic and computer systems. One or more implementations described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The controller 300 may be connected to a network 370. The network 370 may define one or more networks including wired or wireless networks. The wireless network may be a cellular telephone network, an 802.11, 802.16, 802.20, or WiMAX network. Further, such networks may include a public network, such as the Internet, a private network, such as an intranet, or combinations thereof, and may utilize a variety of networking protocols now available or later developed including, but not limited to TCP/IP based networking protocols. The network 370 may include wide area networks (WAN), such as the Internet, local area networks (LAN), campus area networks, metropolitan area networks, a direct connection such as through a Universal Serial Bus (USB) port, or any other networks that may allow for data communication. The network 370 may be configured to couple one computing device to another computing device to enable communication of data between the devices. The network 370 may generally be enabled to employ any form of machine-readable media for communicating information from one device to another. The network 370 may include communication methods by which information may travel between computing devices. The network 370 may be divided into sub-networks. The sub-networks may allow access to all of the other components connected thereto or the sub-networks may restrict access between the components. The network 370 may be regarded as a public or private network connection and may include, for example, a virtual private network or an encryption or other security mechanism employed over the public Internet, or the like.

In accordance with various implementations of the present disclosure, the methods described herein may be implemented by software programs executable by a computer system. Further, in an exemplary, non-limited implementation, implementations can include distributed processing, component/object distributed processing, and parallel processing. Alternatively, virtual computer system processing can be constructed to implement one or more of the methods or functionality as described herein.

Although the present specification describes components and functions that may be implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the steps of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure may be implemented using any appropriate techniques for implementing the functionality described herein. The disclosure is not limited to any particular programming language or operating system.

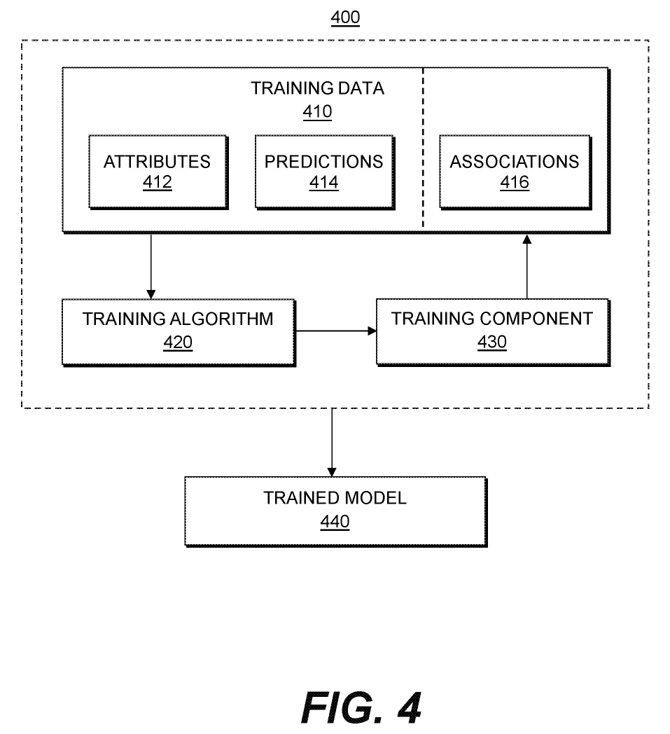

FIG. 4 depicts a flow diagram for training a machine learning model, according to one or more embodiments. FIG. 4 may refer to training a semi-supervised machine learning model. As disclosed herein, one or more implementations disclosed herein may be applied by using a machine learning model. A machine learning model as disclosed herein may be trained using one or more components or operations. As depicted in flow diagram 400 of FIG. 4, training data 410 may include one or more of attributes 412 and targets 414 related to a machine learning model to be trained. The attributes 412 may be from any applicable source including a component, attribute of a component, extracted feature, or set shown in the figures provided herein. The targets 414 may be included for machine learning models generated based on supervised or semi-supervised training. An unsupervised machine learning model might not be trained using targets 414. Targets 414 may include known or desired outputs for future inputs similar to or in the same category as attributes 412 that do not have corresponding known outputs.

The training data 410 and a training algorithm 420 may be provided to a training component 430 that may apply the training data 410 to the training algorithm 420 to generate a trained machine learning model 440. The training component 430 may be provided associations 416 that compare a previous output of the corresponding machine learning model to apply the previous result to re-train the machine learning model. The associations 416 may be used by the training component 430 to update the corresponding machine learning model. The training algorithm 420 may utilize machine learning networks and/or models including, but not limited to a deep learning network such as Deep Neural Networks (DNN), Convolutional Neural Networks (CNN), Fully Convolutional Networks (FCN) and Recurrent Neural Networks (RCN), probabilistic models such as Bayesian Networks and Graphical Models, and/or discriminative models such as Decision Forests and maximum margin methods, or the like.

A machine learning model disclosed herein may be trained by adjusting one or more weights, layers, and/or biases during a training phase. During the training phase, historical or simulated data may be provided as inputs to the model. The model may adjust one or more of its weights, layers, and/or biases based on such historical or simulated information. The adjusted weights, layers, and/or biases may be configured in a production version of the machine learning model (e.g., a trained model) based on the training. Once trained, the machine learning model may output machine learning model outputs in accordance with the subject matter disclosed herein. One or more machine learning models disclosed herein may continuously update based on feedback associated with use or implementation of the machine learning model outputs.

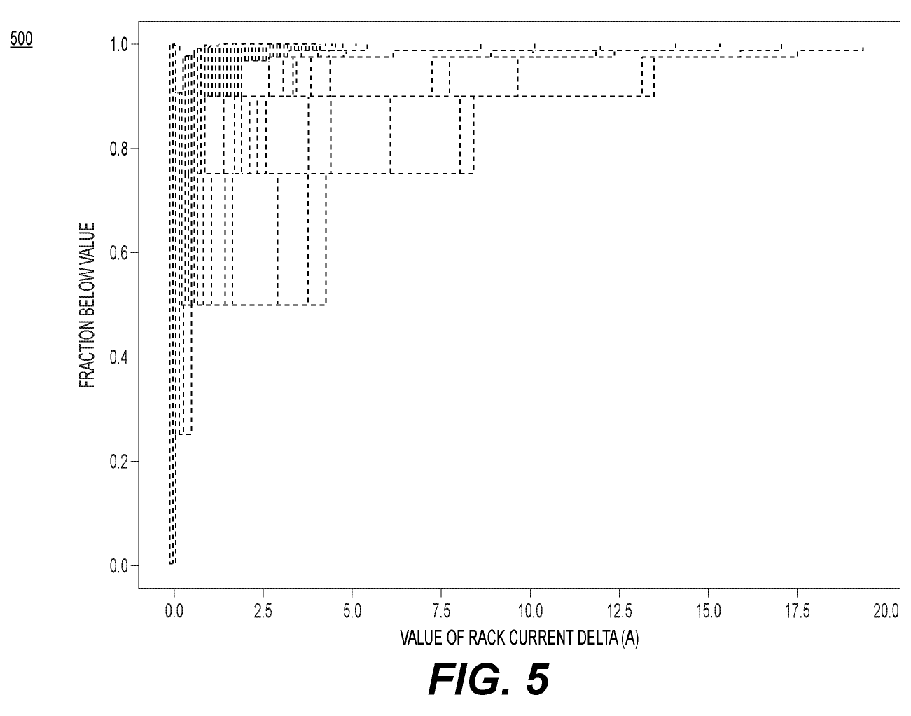

FIG. 5 depicts a high current variation graph showing rack current delta values, according to one or more embodiments. Referring to FIG. 5, a high current variation graph 500 may illustrate the relationship between rack current delta values and fraction below value for battery installations with distinct anomalous behavior. The high current variation graph 500 may show a stepped line pattern that rises sharply from approximately 0.25 at zero amperes to nearly 1.0 at around 2 amperes, then maintains relatively stable values with minor fluctuations across higher rack current delta values extending to 20 amperes. The high current variation graph 500 may demonstrate how some battery installations clearly show battery racks with much higher current delta values, where the current delta may be a first difference in current between each battery rack and a mean current of a plurality of battery racks.

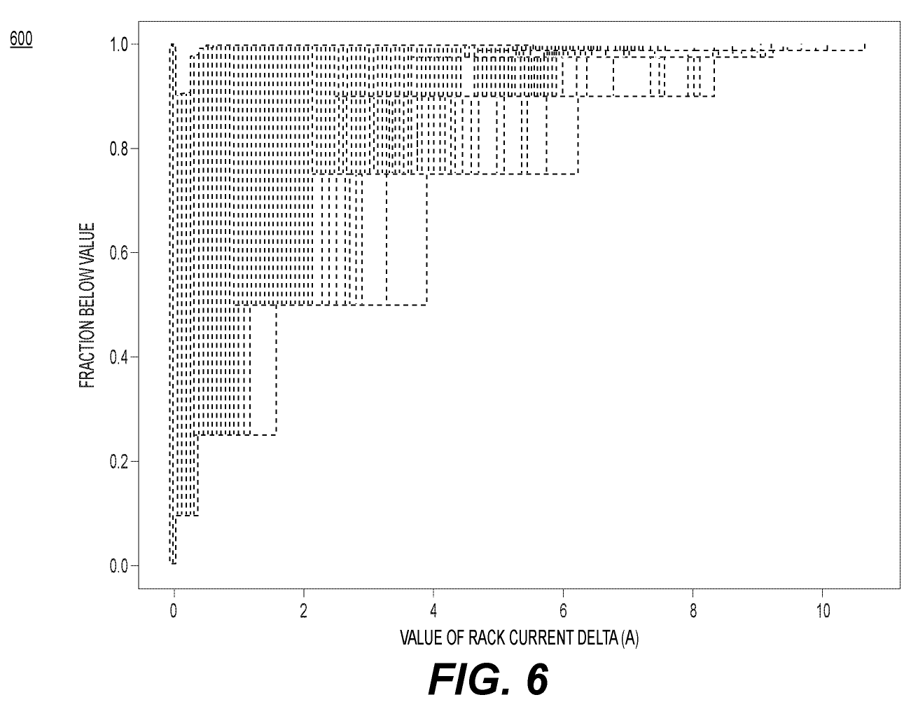

FIG. 6 depicts a gradual current variation graph showing rack current delta values, according to one or more embodiments. With reference to FIG. 6, a gradual current variation graph 600 may display the relationship between rack current delta values and fraction below value for battery installations exhibiting more gradual variation between battery racks. The gradual current variation graph 600 may show data represented by a dashed line pattern, with the fraction below value ranging from 0.0 to 1.0 and the value of rack current delta in amperes ranging from 0 to approximately 10 amperes. The gradual current variation graph 600 may illustrate how other battery installations show more gradual variation between battery racks, where the dashed line pattern shows a stepped progression that rises from near 0.0 at low current delta values to approximately 1.0 at higher current delta values.

Data may be collected from multiple battery installation sites for analysis by the trained machine learning model. The plurality of battery racks may be located at different geographic sites, including sites in different cities or countries, for example. Data collection from these multiple geographic sites may provide selected days of operational data, potentially comprising thousands of datapoints for training and testing the trained machine learning model. The geographic distribution of battery installation sites may enable the trained machine learning model to learn patterns across diverse operating conditions and environmental factors that may affect battery rack performance.

The trained machine learning model may be applied directly to time series current data instead of relying solely on statistical features derived from current deltas. The current data may include a time series of the current data as a data set of normalized values or a data set of absolute values. The time series data for currents may be normalized, instead of using absolute values, before applying the trained machine learning model. This direct application to time series data may enable the trained machine learning model to capture temporal patterns and dynamic behaviors in battery rack current that may not be fully represented by statistical summary metrics. The time series approach may provide enhanced detection capabilities for intermittent loose connections that exhibit time-dependent characteristics across the plurality of battery racks located at the different geographic sites.

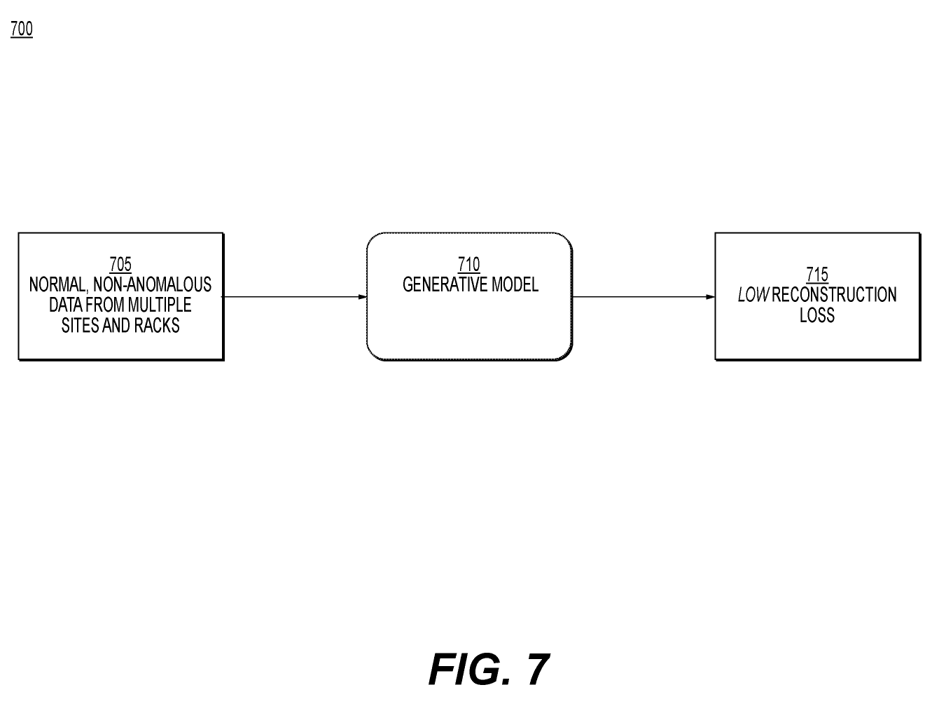

FIG. 7 depicts a flowchart of a training process for anomaly detection using non-anomalous data, according to one or more embodiments. Referring to FIG. 7, a training process 700 may illustrate how the trained machine learning model may be trained using only normal, non-anomalous data for semisupervised learning approaches. The training process 700 may begin with non-anomalous data 705, which may comprise normal, non-anomalous data from multiple sites and racks. The non-anomalous data 705 may be selected by excluding any known intermittent loose connection data during the training phase, ensuring that the trained machine learning model 710 learns to reconstruct only normal operational patterns. The non-anomalous data 705 may be fed into a trained machine learning model 710, which may be configured as a generative model for anomaly detection purposes.

The trained machine learning model 710 may process the non-anomalous data 705 and produce reconstructed output data 715, which may exhibit low reconstruction loss during the training phase. The reconstructed output data 715 may demonstrate that the trained machine learning model 710 has successfully learned to accurately reconstruct normal data patterns from the plurality of battery racks. The training process 700 may utilize only normal, non-anomalous data for training the generative model, enabling the trained machine learning model 710 to learn the characteristics of normal operational behavior without exposure to anomalous conditions.

The trained machine learning model 710 may include one or more of an autoencoder model, a variational autoencoder model, or a GANomaly model, and the trained machine learning model 710 may be trained with the non-anomalous data 705. The trained machine learning model 710 may include a semi-supervised machine learning algorithm trained with normal non-anomalous data, where the trained machine learning model 710 may produce an output with low reconstruction loss for non-anomalous data, and may produce an output with high reconstruction loss for anomalous data to determine an underperforming battery rack.

During the training phase shown in the training process 700, the trained machine learning model 710 may develop the capability to accurately reconstruct data that conforms to normal patterns, resulting in the reconstructed output data 715 with low reconstruction loss. The low reconstruction loss achieved during training may establish a baseline for normal operational behavior, which may later be used during inference to identify anomalous data that produces high reconstruction loss when processed by the trained machine learning model 710.

The current data may be normalized time series data instead of absolute values before applying machine learning methods to the training process 700. Normalized time series data may provide advantages in training the trained machine learning model 710 by reducing the influence of varying operational scales across different battery installation sites. The normalization process may enable the trained machine learning model 710 to focus on relative patterns and deviations rather than absolute current magnitudes, which may vary significantly between different site configurations and operational conditions.

The trained machine learning model 710 may use z-scores to make results insensitive to current magnitudes. Z-score normalization may transform the current data by subtracting the mean and dividing by the standard deviation, creating standardized values that may facilitate comparison across different battery racks and sites. Instead of z-score, a modified or robust z-score using the median and median absolute deviation, respectively, instead of the mean and standard deviation, providing greater robustness to outliers, may be employed. In case standard deviation is smaller than a preset threshold, the corresponding z-scores may be set to zero as it indicates there is no variability in the currents. The preset threshold may be the precision of current measurement, or a fraction (such as 0.01) of the mean current.

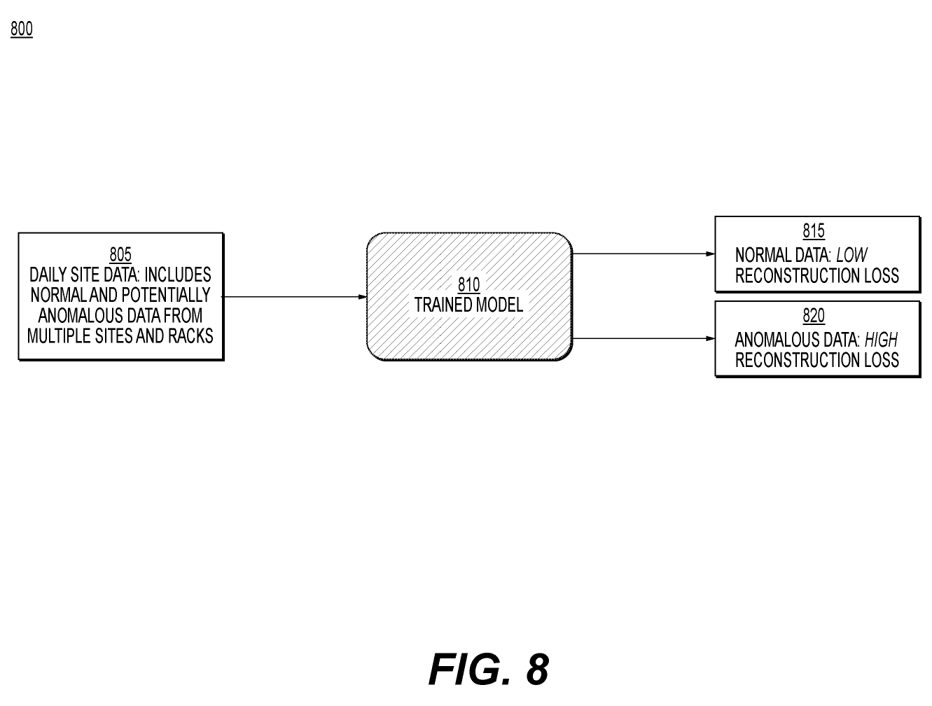

FIG. 8 depicts a flowchart of an inference process for anomaly detection using site data, according to one or more embodiments. Referring to FIG. 8, a training process 800 may illustrate how site data 805 containing both normal and potentially anomalous data may be processed during inference to identify underperforming battery racks. The training process 800 may begin with site data 805, which may include normal and potentially anomalous data from multiple sites and racks. The site data 805 may represent daily operational data collected from battery energy storage systems across different geographic locations, where the data may contain a mixture of normal operational patterns and potential anomalous conditions that may indicate intermittent loose connections or other performance issues.

The site data 805 may be provided as input to a trained machine learning model 810 that has been previously trained using only normal, non-anomalous data as described in the training process 700. The trained machine learning model 810 may process the site data 805 and generate two distinct outputs based on the reconstruction loss characteristics of the input data. The trained machine learning model 810 may have been trained to determine an underperforming battery rack based on current data, enabling the model to distinguish between normal operational patterns and anomalous conditions during inference.

The trained machine learning model 810 may generate reconstructed normal data 815, which may represent data with low reconstruction loss. The reconstructed normal data 815 may correspond to battery rack current data that conforms to the normal operational patterns learned during training, resulting in accurate reconstruction by the trained machine learning model 810. The low reconstruction loss associated with the reconstructed normal data 815 may indicate that the corresponding battery racks are operating within expected parameters and do not exhibit signs of intermittent loose connections or other performance degradation.

The trained machine learning model 810 may also generate reconstructed anomalous data 820, which may represent data with high reconstruction loss. The reconstructed anomalous data 820 may correspond to battery rack current data that deviates significantly from the normal operational patterns learned during training, resulting in poor reconstruction accuracy by the trained machine learning model 810. The high reconstruction loss associated with the reconstructed anomalous data 820 may indicate the presence of an underperforming battery rack that may be experiencing intermittent loose connections or other anomalous conditions.

The trained machine learning model 810 may determine an underperforming battery rack of a plurality of battery racks by comparing a current delta for each battery rack of the plurality of battery racks to a performance threshold. Based on the comparing, the trained machine learning model 810 may determine the underperforming battery rack of the plurality of battery racks when the reconstruction loss exceeds the performance threshold range. The performance threshold for the scaled anomaly score may be from approximately 0.2 to 0.4, where the scaled anomaly score may represent the scaled mean square error reconstruction loss calculated between the original input data and reconstructed output data for a test dataset.

The trained machine learning model 810 may determine a rack deviation by determining a second difference between a mean current of each of the plurality of battery racks and a current of the underperforming battery rack over a period of time. The period of time may be thirty second intervals over 24 hours, providing continuous monitoring of battery rack performance throughout daily operational cycles. The rack deviation may represent the magnitude of current difference that indicates the severity of the performance degradation in the underperforming battery rack.

The training process 800 may enable determination of an intermittent loose connection of the underperforming battery rack based on the rack deviation. The intermittent loose connection may be characterized by higher resistance and lower rack current relative to normal battery racks, which may be detected through the analysis of reconstruction loss patterns generated by the trained machine learning model 810. The method for controlling a battery energy storage system may utilize the training process 800 to automatically identify and respond to intermittent loose connections before they progress to complete failure.

The trained machine learning model 810 may identify early warning signs with medium reconstruction loss in addition to anomalous data with high reconstruction loss. Early warning signs may correspond to battery rack current data that exhibits moderate deviations from normal operational patterns, resulting in reconstruction loss values that fall between the low reconstruction loss of normal data and the high reconstruction loss of clearly anomalous data. The medium reconstruction loss may indicate gradual performance degradation that may serve as a precursor to more severe anomalous conditions, enabling proactive maintenance interventions before complete failure occurs.

The early warning detection capability may provide enhanced monitoring of battery rack performance by identifying subtle changes in current patterns that may not yet constitute clear anomalies but may indicate developing issues. The medium reconstruction loss threshold may be established between the performance threshold range of approximately 0.2 to 0.4 in the scaled anomaly score, allowing the trained machine learning model 810 to distinguish between normal operation, early warning conditions, and clearly anomalous conditions. This multi-level detection approach may enable maintenance teams to schedule interventions during planned maintenance windows rather than responding to emergency failures.

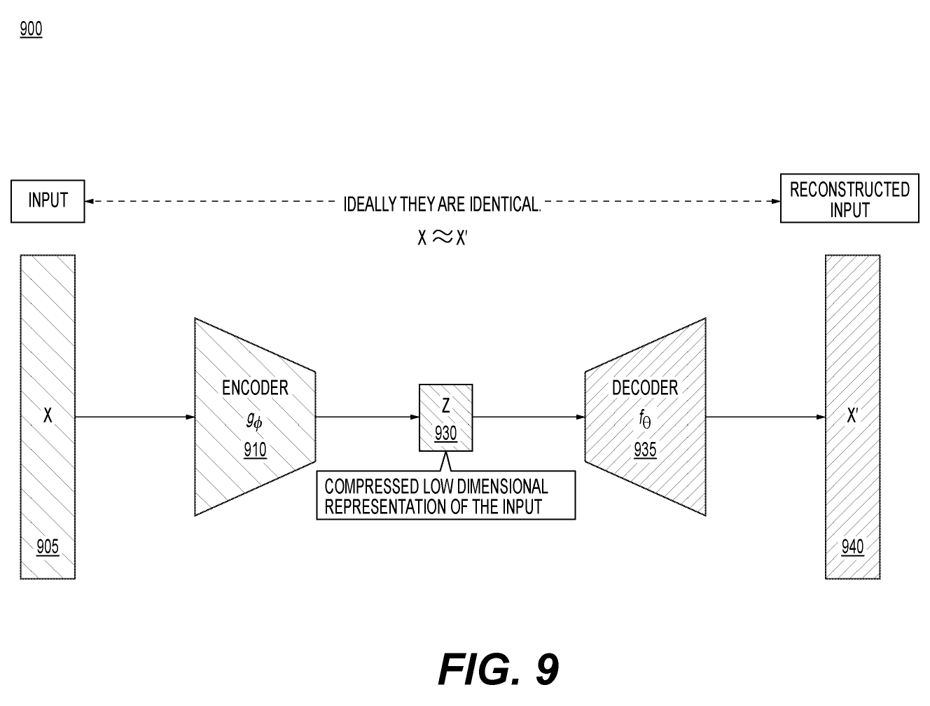

FIG. 9 depicts a block diagram of a trained machine learning model configured as an autoencoder, according to one or more embodiments. Referring to FIG. 9, a trained machine learning model 900 may be configured for anomaly detection using an autoencoder architecture. The trained machine learning model 900 may receive input data 905, which may represent current data from battery racks in a battery energy storage system. The input data 905 may include statistical metrics of current delta distributions, such as quantiles, standard deviation, interquartile range, and spreads calculated from thirty-second intervals over a 24-hour period.

The input data 905 may be processed through an encoder 910, which may implement a bottleneck architecture to learn a reduced representation of the input data 905. The encoder 910 may compress the input data 905 into a lower-dimensional representation, reducing the complexity while preserving the most relevant features for anomaly detection. The encoder 910 may utilize multiple layers with decreasing numbers of neurons to progressively compress the input data 905 into the reduced dimensional space.

The encoder 910 may compress the input data 905 into code 930, which may represent a latent representation or bottleneck layer of the autoencoder architecture. The code 930 may serve as a compressed low-dimensional representation of the input data 905, capturing the most significant patterns and features from the original battery rack current data. The code 930 may contain the encoded information necessary for the decoder to reconstruct the original input data 905.

A decoder 935 may receive the code 930 and reconstruct the original input to produce reconstructed input 940. The decoder 935 may implement a mirror architecture to the encoder 910, with layers that progressively expand the dimensionality from the code 930 back to the original input dimensions. The decoder 935 may utilize multiple layers with increasing numbers of neurons to decompress the code 930 and generate the reconstructed input 940.

The reconstructed input 940 may ideally approximate the original input data 905, where the similarity between the input data 905 and the reconstructed input 940 may be measured using reconstruction loss metrics such as mean square error. During training with normal, non-anomalous data, the trained machine learning model 900 may learn to minimize the reconstruction loss, enabling accurate reconstruction of normal operational patterns. During inference, when anomalous data may be provided as the input data 905, the trained machine learning model 900 may produce a reconstructed input 940 with higher reconstruction loss, thereby enabling identification of anomalies based on the deviation between the input data 905 and the reconstructed input 940.

The trained machine learning model 900 may include the encoder 910 and the decoder 935 as core components of the autoencoder architecture. The encoder 910 and the decoder 935 may work together to learn a compressed representation of normal battery rack operational patterns during training, and may subsequently identify deviations from these learned patterns during inference to detect intermittent loose connections or other anomalous conditions.

The trained machine learning model 900 may utilize deep neural network (DNN) architecture for processing statistical features derived from current delta measurements. However, the trained machine learning model 900 may alternatively use convolutional neural network (CNN) architecture for time series data instead of DNN architecture. The CNN architecture may provide advantages when the input data 905 includes time series current data directly, as convolutional layers may be better suited for capturing temporal patterns and local dependencies in sequential data.

The CNN architecture may include convolutional layers that may apply filters across temporal dimensions of the time series data, enabling the encoder 910 to identify local patterns and temporal correlations in battery rack current measurements. The convolutional layers may be followed by pooling layers that may reduce the temporal resolution while preserving important features, contributing to the compression function of the encoder 910. The decoder 935 in a CNN-based architecture may utilize transposed convolutional layers or upsampling layers to reconstruct the time series data from the compressed code 930.

The choice between DNN and CNN architecture for the trained machine learning model 900 may depend on the format of the input data 905. When the input data 905 comprises statistical summary metrics such as quantiles and standard deviations, DNN architecture may be appropriate for processing these tabular features. When the input data 905 comprises raw time series current data or normalized time series data, CNN architecture may provide enhanced capability for detecting temporal anomalies and patterns that may indicate intermittent loose connections in battery racks.

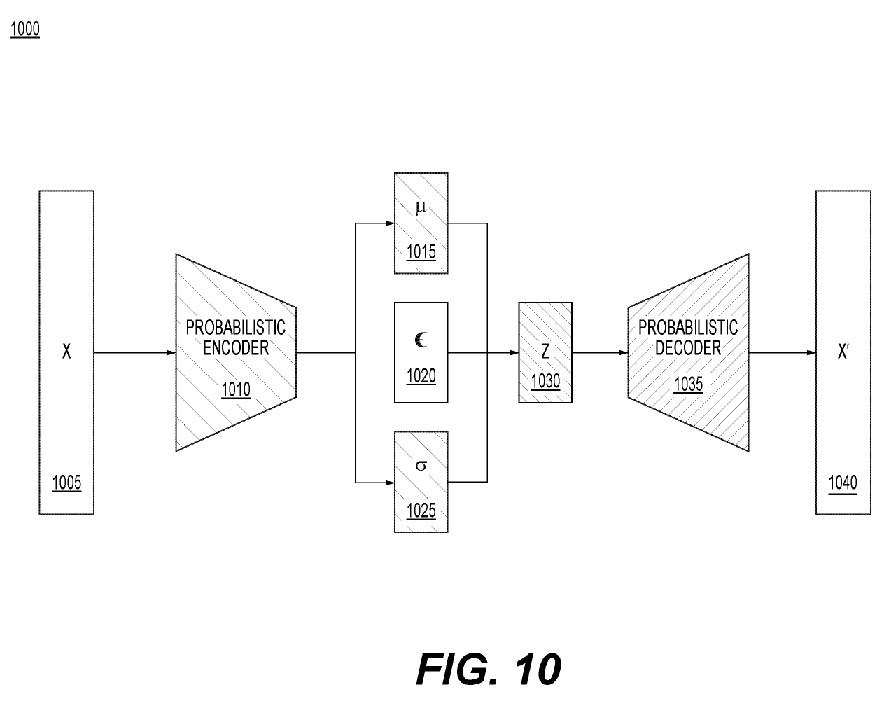

FIG. 10 depicts a block diagram of a trained machine learning model configured as a variational autoencoder, according to one or more embodiments. Referring to FIG. 10, a trained machine learning model 1000 may be configured as a variational autoencoder (VAE) for anomaly detection in battery energy storage systems. The trained machine learning model 1000 may receive input data 1005, which may represent current data from battery racks including statistical metrics of current delta distributions or time series current measurements. The input data 1005 may include features such as quantiles, standard deviation, interquartile range, and spreads calculated from battery rack current deviations over specified time intervals.

The input data 1005 may be processed through an encoder 1010, which may implement a probabilistic encoding scheme that differs from the deterministic encoding used in standard autoencoder architectures. The encoder 1010 may generate two distinct outputs from the input data 1005: a mean 1015 (μ) and a standard deviation 1025 (σ). The mean 1015 may represent the central tendency of the latent space distribution, while the standard deviation 1025 may represent the variability or uncertainty in the encoded representation.

A random sampled variable 1020 (ε) may be combined with the mean 1015 and the standard deviation 1025 through a reparameterization process to produce a latent variable 1030 (z). The random sampled variable 1020 may be sampled from a standard normal distribution, providing stochastic variation that enables the probabilistic nature of the variational autoencoder. The latent variable 1030 may be calculated using the reparameterization trick, which may shift the stochasticity to the random sampled variable 1020 while maintaining differentiability for gradient-based training.

The latent variable 1030 may represent a compressed representation of the input data 1005 sampled from a probabilistic distribution rather than a fixed deterministic encoding. The probabilistic encoding may enable the trained machine learning model 1000 to capture uncertainty and variability in normal operational patterns of battery racks, potentially providing more robust anomaly detection compared to deterministic autoencoder approaches. The latent variable 1030 may be constrained to approximate a prior distribution, typically a standard Gaussian distribution, through the training process.

The latent variable 1030 may be fed into a decoder 1035, which may reconstruct the original input to generate a reconstructed input 1040 (x'). The decoder 1035 may implement a generative process that maps from the latent space back to the original input space, producing the reconstructed input 1040 that approximates the original input data 1005. The decoder 1035 may utilize multiple layers with increasing dimensionality to transform the latent variable 1030 back to the original input dimensions.

The trained machine learning model 1000 may implement a beta-variational autoencoder (β-VAE) architecture that applies a weight term beta to the KL divergence in the loss function. The total loss function may comprise the sum of reconstruction loss and KL divergence between a prior distribution, assumed to be Gaussian, and a posterior distribution learned by the encoder 1010. The beta weight term may be applied to the KL divergence component, allowing control over the balance between reconstruction accuracy and regularization of the latent space distribution.

The beta weight term may influence the trade-off between reconstruction fidelity and disentanglement of latent representations in the trained machine learning model 1000. Higher beta values may increase the emphasis on regularization, potentially leading to more disentangled latent representations but may reduce reconstruction accuracy. Lower beta values may prioritize reconstruction accuracy but may result in less structured latent space organization. The beta parameter may be tuned during training to optimize the performance of the trained machine learning model 1000 for detecting intermittent loose connections in battery racks.

During training with non-anomalous data, the trained machine learning model 1000 may learn to reconstruct normal patterns with low reconstruction loss while maintaining the latent variable 1030 distribution close to the prior distribution through the KL divergence term. During inference, anomalous data may result in higher reconstruction loss when processed by the trained machine learning model 1000, enabling identification of underperforming battery racks. The probabilistic nature of the encoding process may provide additional robustness in distinguishing between normal operational variations and true anomalous conditions that may indicate intermittent loose connections.

The trained machine learning model 1000 may provide advantages over standard autoencoder architectures by incorporating probabilistic modeling and regularization through the KL divergence term. The variational approach may enable better generalization to unseen data and may provide more stable anomaly detection performance across different battery installation sites and operating conditions. The beta-weighted KL divergence may allow fine-tuning of the model behavior to optimize detection sensitivity for specific types of anomalies such as intermittent loose connections in battery energy storage systems.

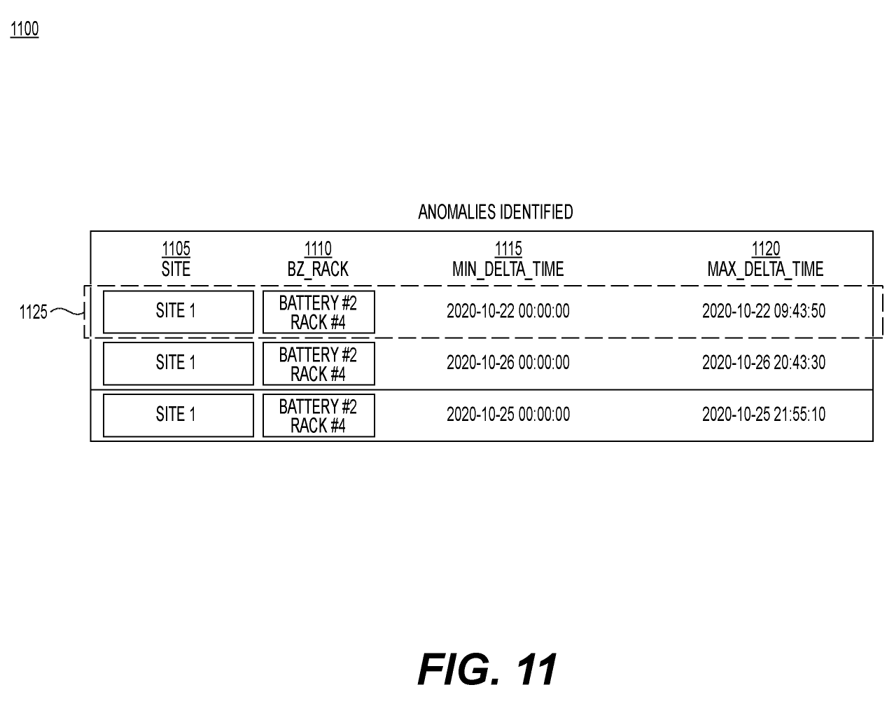

FIG. 11 depicts a detected anomaly table showing anomalies identified by a trained machine learning model, according to one or more embodiments. Referring to FIG. 11, a detected anomaly table 1100 may display anomalies identified by the trained machine learning model 1000 configured as a beta-variational autoencoder. The detected anomaly table 1100 may include columns for a site 1105, a rack 1110, a minimum delta time 1115, and a maximum delta time 1120. The site 1105 may identify the geographic location of the battery installation where anomalous conditions have been detected, such as "SITE 1" corresponding to a specific battery energy storage facility. The rack 1110 may specify the particular battery rack within the site 1105 that exhibits anomalous behavior, such as "BATTERY 2 RACK 4" indicating the fourth rack in the second battery zone.

The minimum delta time 1115 may indicate the start time of the anomalous period, while the maximum delta time 1120 may indicate the end time of the anomalous period for each detected anomaly. Three samples 1125 may be listed in the detected anomaly table 1100, each corresponding to the site 1105 identified as "SITE 1" and the rack 1110 identified as "BATTERY 2 RACK 4". The minimum delta time 1115 for the three samples 1125 may show dates of 2020-10-22 00:00:00, 2020-10-26 00:00:00, and 2020-10-25 00:00:00 respectively, while the maximum delta time 1120 for the three samples 1125 may show corresponding end times of 2020-10-22 09:43:50, 2020-10-26 20:43:30, and 2020-10-25 21:55:10 respectively.

The detected anomaly table 1100 may demonstrate how the trained machine learning model 1000 may identify specific time periods when an underperforming battery rack exhibits anomalous behavior that may indicate intermittent loose connections. The temporal information provided by the minimum delta time 1115 and the maximum delta time 1120 may enable maintenance teams to correlate detected anomalies with operational events or environmental conditions that may have contributed to the performance degradation. The samples 1125 may represent distinct anomalous events detected across multiple days, indicating that the intermittent loose connection may manifest as recurring anomalous periods rather than continuous degradation.

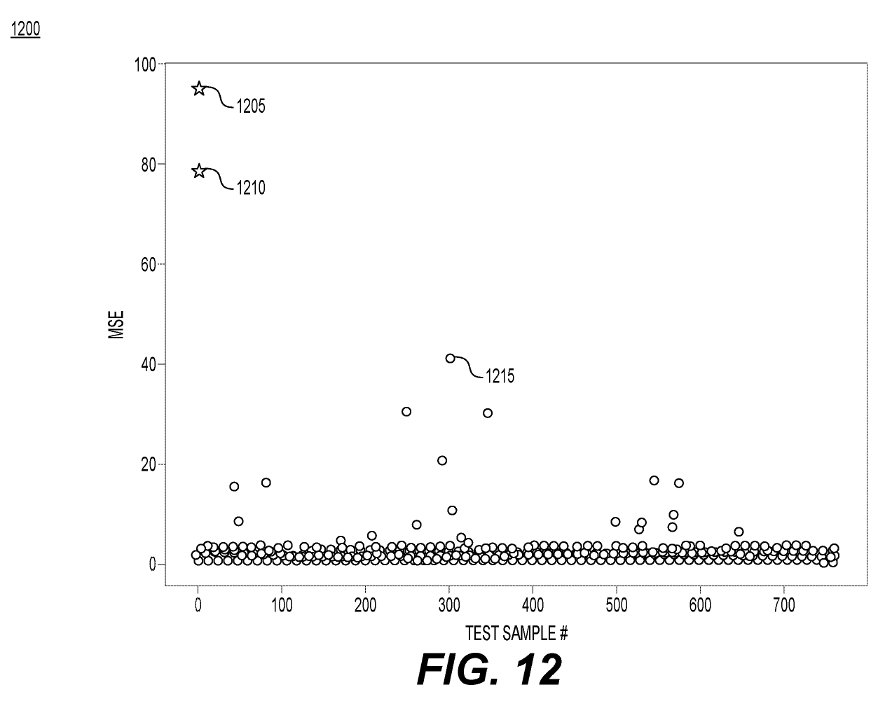

FIG. 12 depicts a mean square error graph showing reconstruction loss values, according to one or more embodiments. With reference to FIG. 12, a mean square error graph 1200 may show reconstruction loss values plotted against test sample numbers for the trained machine learning model 1000. The mean square error graph 1200 may display mean square error (MSE) values on the vertical axis ranging from 0 to 100, and test sample numbers on the horizontal axis ranging from 0 to approximately 750. The mean square error graph 1200 may include anomalous data 1205 and anomalous data 1210, which may appear at higher MSE values near the left portion of the graph, indicating significantly elevated reconstruction loss compared to normal operational data.

The mean square error graph 1200 may also include early warning data 1215, which may appear at a moderate MSE value in the middle portion of the graph. The early warning data 1215 may represent battery rack current data that exhibits moderate deviations from normal operational patterns, resulting in reconstruction loss values that fall between the low reconstruction loss of normal data and the high reconstruction loss of the anomalous data 1205 and anomalous data 1210. The majority of data points may cluster near the bottom of the mean square error graph 1200 at low MSE values, indicating normal non-anomalous operational conditions.

The trained machine learning model 1000 may determine an anomaly score for an underperforming battery rack based on a rack deviation for the underperforming battery rack. The anomaly score may be derived from the reconstruction loss values shown in the mean square error graph 1200, where higher reconstruction loss may correspond to higher anomaly scores indicating greater likelihood of intermittent loose connections or other performance issues. The anomaly score may provide a quantitative measure of the severity of the anomalous condition, enabling prioritization of maintenance interventions based on the magnitude of the detected deviation.

The trained machine learning model 1000 may provide scaled anomaly scores from 0 to 1, allowing user-defined threshold setting for anomaly detection. The scaled anomaly scores may enable operators to adjust the sensitivity of the anomaly detection system based on operational requirements and maintenance capabilities. A threshold near 0.5 may provide balanced detection sensitivity, while higher thresholds may reduce false positive detections at the cost of potentially missing subtle anomalies, and lower thresholds may increase detection sensitivity but may result in more frequent alerts requiring investigation.

The method for controlling a battery energy storage system may further include receiving temperature data associated with the underperforming battery rack and determining the anomaly score for the underperforming battery rack based on the rack deviation for the underperforming battery rack and the temperature data for the underperforming battery rack. The temperature data may provide additional context for interpreting current deviations, as thermal conditions may influence battery rack performance and may help distinguish between anomalies caused by intermittent loose connections and those caused by thermal effects. The combined analysis of current deviation and temperature data may improve the accuracy of anomaly score determination by accounting for environmental factors that may affect battery rack operation.

The method may further include grouping the anomaly score for the underperforming battery rack into one of a first group and a second group, based on the rack deviation for the underperforming battery rack, wherein rack deviations of the first group may be less than rack deviations of the second group. The first group may correspond to early warning conditions with moderate anomaly scores, while the second group may correspond to severe anomalous conditions with high anomaly scores requiring immediate attention. The grouping may enable differentiated response protocols, where the first group may trigger scheduled maintenance planning and the second group may trigger immediate investigation or emergency shutdown procedures.

The method may include generating a notification based on the grouping, where the notification may be customized according to the severity level indicated by the group assignment. Notifications for the first group may include maintenance scheduling recommendations and trend analysis reports, while notifications for the second group may include immediate alerts with detailed diagnostic information and recommended corrective actions. The notification system may enable efficient allocation of maintenance resources by providing clear indication of anomaly severity and urgency level based on the anomaly score grouping derived from the reconstruction loss analysis shown in the mean square error graph 1200.

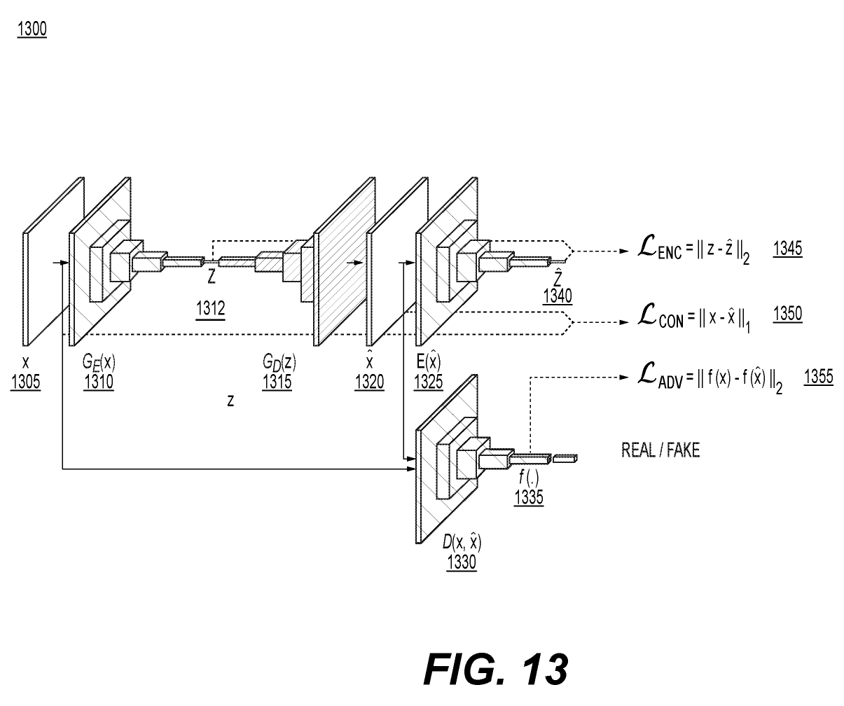

FIG. 13 depicts a block diagram of a trained machine learning model configured as a GANomaly model for anomaly detection, according to one or more embodiments. Referring to FIG. 13, a trained machine learning model 1300 may be configured as a GANomaly architecture for anomaly detection in battery energy storage systems. The trained machine learning model 1300 may implement a dual structure that includes a generator with an encoder-decoder-encoder configuration and a separate discriminator component. The GANomaly architecture may provide enhanced anomaly detection capabilities by combining generative modeling with adversarial training to identify intermittent loose connections and other performance anomalies in battery racks.

The trained machine learning model 1300 may include an input layer 1305 that receives input data for processing. The input layer 1305 may accept current data from battery racks, including statistical metrics of current delta distributions or time series current measurements collected from battery energy storage systems. The input data may flow from the input layer 1305 to an input encoder 1310, which may process the input data to generate a compressed representation of the battery rack operational patterns.

The input encoder 1310 may process the input data to generate a vector 1312, which may represent a reduced or encoded representation of the input data. The vector 1312 may capture the most significant features and patterns from the original battery rack current data in a lower-dimensional latent space. The input encoder 1310 may utilize multiple layers with decreasing numbers of neurons to progressively compress the input data into the vector 1312, similar to the encoder architectures described in previous autoencoder implementations.

The vector 1312 may be provided to a decoder 1315, which may reconstruct the data and generate an output at an output layer 1320. The decoder 1315 may implement a generative process that maps from the latent space representation in the vector 1312 back to the original input space dimensions. The output layer 1320 may produce reconstructed data that corresponds to the input data, where the reconstruction quality may indicate whether the input data represents normal or anomalous battery rack behavior.

The output from the output layer 1320 may be further processed by an output encoder 1325, which may generate a vector prime 1340. The output encoder 1325 may implement a second encoding stage that compresses the reconstructed output data back into a latent space representation. The vector prime 1340 may represent an encoded representation of the reconstructed output data, enabling comparison with the original vector 1312 to assess the consistency of the encoding-decoding process.

The trained machine learning model 1300 may include a discriminator 1330 that receives input from the output encoder 1325. The discriminator 1330 may evaluate the authenticity of the reconstructed data by analyzing the encoded representations and determining whether the data corresponds to real or generated patterns. The discriminator 1330 may provide classification results through a softmax layer 1335, which may determine whether the data represents genuine operational patterns or anomalous conditions that may indicate intermittent loose connections.

The GANomaly architecture may include a generator with encoder-decoder-encoder structure and a separate discriminator component. The generator component may comprise the input encoder 1310, the decoder 1315, and the output encoder 1325, which work together to encode, reconstruct, and re-encode the input data. The separate discriminator component may comprise the discriminator 1330 and the softmax layer 1335, which may evaluate the quality and authenticity of the generated reconstructions to distinguish between original and reconstructed data, and ultimately to distinguish between normal and anomalous battery rack operational patterns.

The trained machine learning model 1300 may utilize multiple loss functions to evaluate performance and train the GANomaly architecture. An encoder loss 1345 may be calculated based on the difference between the vector 1312 and the vector prime 1340, which may be represented as L_ENC = ||z - ẑ||_2. The encoder loss 1345 may measure the consistency between the original encoded representation and the encoded representation of the reconstructed data, ensuring that the encoding-decoding process preserves the latent space structure.

A contextual loss 1350 may be determined based on the difference between the input data x and the reconstructed output x̂, which may be represented as L_CON = ||x - x̂||_1. The contextual loss 1350 may measure the reconstruction accuracy by comparing the original input data with the reconstructed output from the decoder 1315. The contextual loss 1350 may provide a direct measure of how well the trained machine learning model 1300 can reconstruct normal operational patterns, where higher contextual loss may indicate anomalous conditions.

An adversarial loss 1355 may be computed based on the discriminator output, which may be represented as L_ADV = ||f(x) - f(x̂)||_2. The adversarial loss 1355 may measure the difference between the discriminator responses to real and reconstructed data, encouraging the generator to produce reconstructions that are indistinguishable from real data according to the discriminator 1330. The adversarial loss 1355 may enhance the quality of reconstructions for normal data while making anomalous data more easily detectable through poor reconstruction quality.

The combination of the encoder loss 1345, the contextual loss 1350, and the adversarial loss 1355 may collectively enable the trained machine learning model 1300 to identify anomalous data by measuring reconstruction accuracy and consistency between the original and reconstructed representations. During training with normal, non-anomalous data, the trained machine learning model 1300 may learn to minimize these loss functions, resulting in accurate reconstructions and consistent latent representations for normal battery rack operational patterns. During inference, anomalous data that deviates from learned normal patterns may result in higher loss values, enabling identification of underperforming battery racks that may be experiencing intermittent loose connections or other performance issues.

The GANomaly architecture may provide advantages over standard autoencoder and variational autoencoder approaches by incorporating adversarial training through the discriminator 1330. The adversarial training process may improve the quality of reconstructions for normal data while enhancing the detectability of anomalous conditions through the combined evaluation of multiple loss functions. The dual structure of the generator and discriminator components may enable more robust anomaly detection across diverse battery installation sites and operating conditions, providing enhanced capability for identifying intermittent loose connections in battery energy storage systems.

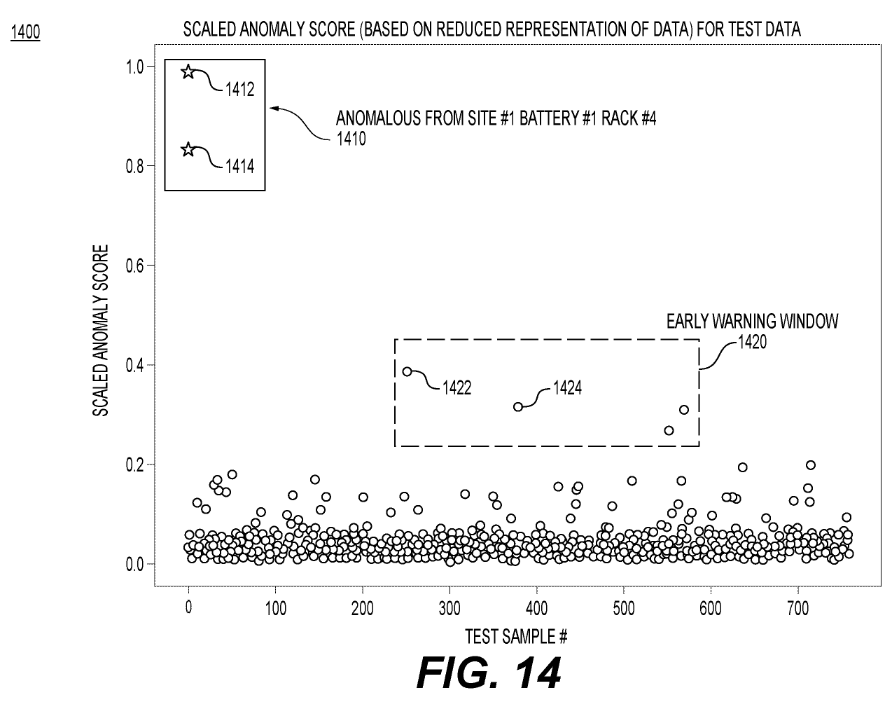

FIG. 14 depicts a scaled anomaly score graph based on original input and reconstructed data, according to one or more embodiments. Referring to FIG. 14, a scaled anomaly score graph 1400 may display anomaly detection results generated by the trained machine learning model 1300 configured as a GANomaly architecture. A scaled anomaly score plot may be obtained from various generative models (e.g., autoencoder, variational autoencoder, or GANomaly) by scaling the MSE (mean square error reconstruction loss between original and reconstructed inputs) for a test dataset between 0 and 1. For GANomaly, an alternative scaled anomaly score plot may be obtained by scaling the reconstruction loss between the first and second reduced representations, z and z_hat in FIG. 13, from 0 to 1 for a test dataset. The scaled anomaly score plot can be determined for any of these methods and is not limited to GANomaly. The scaled anomaly score graph 1400 may show scaled anomaly score values ranging from 0.0 to 1.0 on the vertical axis, while the horizontal axis may display test sample numbers ranging from 0 to approximately 750. The scaled anomaly score graph 1400 may provide a normalized representation of anomaly likelihood, where higher scores may indicate greater probability of anomalous conditions such as intermittent loose connections in battery racks.

The scaled anomaly score graph 1400 may include anomalous rack data 1410 from a specific battery installation site and rack configuration. The anomalous rack data 1410 may comprise anomalous data 1412 and anomalous data 1414, which may be marked with distinctive symbols at specific test sample locations. The anomalous data 1412 and the anomalous data 1414 may exhibit significantly elevated anomaly scores compared to normal operational data, indicating clear deviations from learned normal patterns that may correspond to intermittent loose connections or other performance degradation in the battery rack.

An early warning window 1420 may be indicated within the scaled anomaly score graph 1400, encompassing a range of test samples that exhibit moderate anomaly scores. The early warning window 1420 may contain early warning data 1422 and early warning data 1424, which may represent battery rack operational conditions that deviate moderately from normal patterns but may not yet constitute clear anomalous conditions. The early warning data 1422 and the early warning data 1424 may provide advance indication of developing performance issues, enabling proactive maintenance interventions before conditions progress to the severity levels indicated by the anomalous data 1412 and the anomalous data 1414.

The scaled anomaly score graph 1400 may demonstrate how the trained machine learning model 1300 may provide graduated anomaly detection capabilities, distinguishing between normal operation, early warning conditions, and clearly anomalous conditions. The scaled anomaly scores may enable operators to establish multiple threshold levels for different response protocols, where scores approaching 1.0 may trigger immediate investigation or emergency procedures, while moderate scores within the early warning window 1420 may initiate scheduled maintenance planning and enhanced monitoring activities.

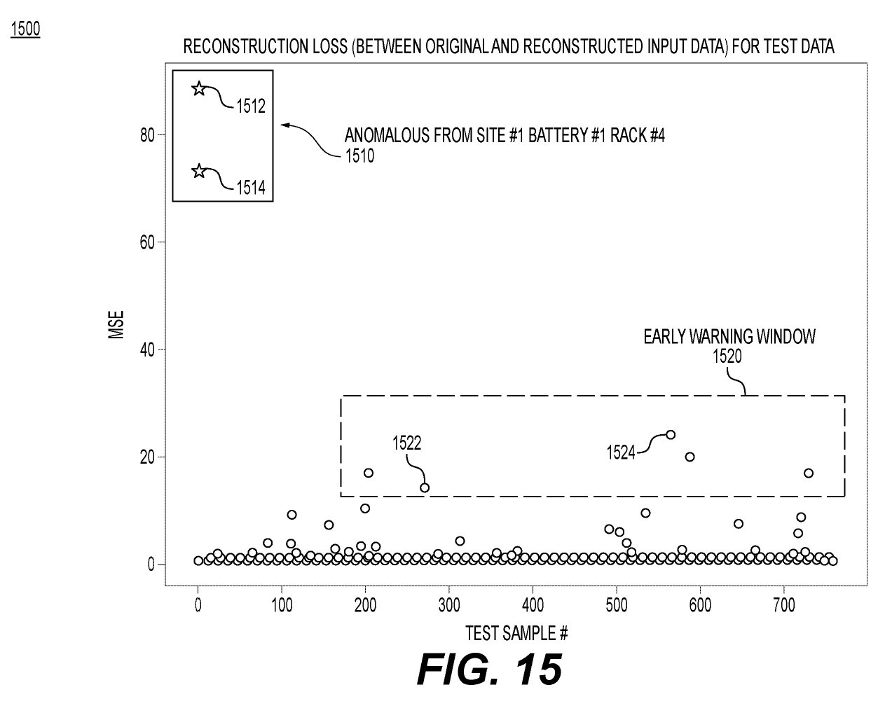

FIG. 15 depicts a reconstruction loss graph showing mean square error between original input and reconstructed input data, according to one or more embodiments. With reference to FIG. 15, a reconstruction loss graph 1500 may show mean square error (MSE) values between original and reconstructed input data for the same test dataset analyzed in the scaled anomaly score graph 1400. The reconstruction loss graph 1500 may display reconstruction loss on the vertical axis and test sample numbers on the horizontal axis, providing a complementary view of anomaly detection results generated by the trained machine learning model 1300. The reconstruction loss measurements may directly reflect the ability of the GANomaly architecture to accurately reconstruct input data, where higher reconstruction loss may indicate anomalous conditions.

The reconstruction loss graph 1500 may include anomalous rack data 1510, which may correspond to the same battery rack and time periods represented in the anomalous rack data 1410 from the scaled anomaly score graph 1400. The anomalous rack data 1510 may comprise anomalous data 1512 and anomalous data 1514, which may exhibit significantly higher reconstruction loss values compared to normal operational data. The anomalous data 1512 and the anomalous data 1514 may demonstrate how the trained machine learning model 1300 may fail to accurately reconstruct anomalous input patterns, resulting in elevated MSE values that correlate with the high anomaly scores shown in the scaled anomaly score graph 1400.

An early warning window 1520 may be indicated in the reconstruction loss graph 1500, encompassing test samples that exhibit moderately elevated reconstruction loss values. The early warning window 1520 may contain early warning data 1522 and early warning data 1524, which may show reconstruction loss values that fall between the low reconstruction loss of normal data and the high reconstruction loss of the anomalous data 1512 and the anomalous data 1514. The early warning data 1522 and the early warning data 1524 may correspond to the early warning conditions identified in the early warning window 1420 of the scaled anomaly score graph 1400, providing consistent detection of developing performance issues across both anomaly score and reconstruction loss metrics.

The reconstruction loss graph 1500 may demonstrate the correlation between reconstruction loss and anomaly scores generated by the trained machine learning model 1300. The majority of test samples may cluster near the bottom of the reconstruction loss graph 1500 with low MSE values, indicating normal non-anomalous operational conditions where the GANomaly architecture may successfully reconstruct input data. The elevated reconstruction loss values associated with the anomalous data 1512, the anomalous data 1514, the early warning data 1522, and the early warning data 1524 may provide quantitative measures of deviation severity that may be used to establish performance thresholds for automated anomaly detection systems.

The trained machine learning model 1300 may be applied to voltage and temperature time series data for anomaly detection in addition to current data analysis. The GANomaly architecture may process voltage measurements from battery racks to identify anomalous voltage patterns that may indicate intermittent loose connections, cell degradation, or other electrical issues that may not be fully captured through current analysis alone. Voltage anomalies may manifest as unexpected voltage drops, irregular voltage distributions across battery modules, or voltage patterns that deviate from normal charging and discharging profiles learned during training.

Temperature time series data may provide additional diagnostic information for anomaly detection in battery energy storage systems, where the trained machine learning model 1300 may identify thermal anomalies that may indicate developing performance issues. Temperature anomalies may include localized heating patterns that may suggest increased resistance due to loose connections, thermal runaway conditions, or cooling system malfunctions that may affect battery rack performance. The combination of current, voltage, and temperature data analysis may provide comprehensive monitoring capabilities that may enhance the accuracy and reliability of intermittent loose connection detection.

The application of the trained machine learning model 1300 to voltage and temperature time series data may utilize the same GANomaly architecture principles demonstrated for current data analysis. The input layer 1305 may accept voltage or temperature measurements instead of or in addition to current data, while the input encoder 1310, the decoder 1315, the output encoder 1325, and the discriminator 1330 may process these alternative data types using the same encoder-decoder-encoder structure with adversarial training. The encoder loss 1345, the contextual loss 1350, and the adversarial loss 1355 may be calculated for voltage and temperature reconstructions, enabling detection of anomalous patterns across multiple measurement domains.

The multi-modal approach combining current, voltage, and temperature data analysis may provide enhanced anomaly detection capabilities by capturing different aspects of battery rack performance degradation. Intermittent loose connections may manifest differently across these measurement domains, where current anomalies may indicate immediate electrical performance issues, voltage anomalies may reveal connection quality problems, and temperature anomalies may suggest thermal consequences of electrical resistance changes. The trained machine learning model 1300 may be configured to process these multiple data streams simultaneously or sequentially to provide comprehensive anomaly detection coverage for battery energy storage systems.

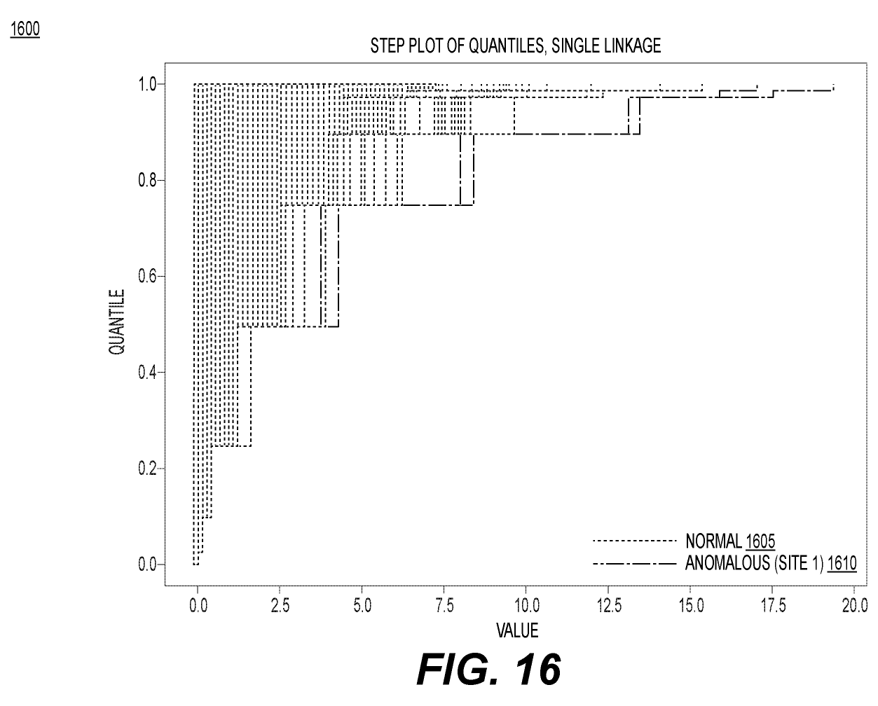

In one or more embodiments, unsupervised machine learning based on agglomerative hierarchical clustering may be applied to the features of the rack current deltas for underperforming rack currents. The agglomerative hierarchical clustering may be based on single linkage or complete linkage, and may be used to cluster the data into two clusters, one corresponding to normal racks and the other corresponding to anomalous racks. FIG. 16 depicts a single linkage quantile graph showing step plots for rack current data analysis, according to one or more embodiments. Referring to FIG. 16, a single linkage quantile graph 1600 may show step plots of quantiles for rack current data analysis using single linkage clustering methodology. The single linkage quantile graph 1600 may display quantile values on the vertical axis ranging from 0.0 to 1.0, while the horizontal axis may show rack current delta value measurements extending from 0.0 to 20.0. The single linkage quantile graph 1600 may demonstrate how the trained machine learning model may distinguish between different types of battery rack operational patterns using single linkage criteria for clustering analysis.

The single linkage quantile graph 1600 may include normal site data 1605, which may be represented by a dotted line pattern showing quantile values that remain relatively low across the value range. The normal site data 1605 may correspond to battery rack current measurements that exhibit typical operational characteristics without significant deviations from expected performance patterns. The normal site data 1605 may demonstrate how battery racks operating under normal conditions may produce current delta distributions with quantile patterns that cluster together when analyzed using single linkage clustering methodology.

The single linkage quantile graph 1600 may also include anomalous site data 1610, which may be represented by a dash-dot line pattern that exhibits elevated quantile values, particularly in the mid-range values between approximately 5.0 and 15.0. The anomalous site data 1610 may correspond to battery rack current measurements that deviate significantly from normal operational patterns, potentially indicating intermittent loose connections or other performance degradation issues. The distinction between the normal site data 1605 and the anomalous site data 1610 may demonstrate how single linkage clustering may identify large deviations in underperforming battery racks by using minimum distance criteria to group similar data points.

The machine learning model may include an unsupervised machine learning algorithm, where the machine learning model may be configured to cluster current data into clustered data based on reducing within-cluster distance and separating different clusters. The machine learning model may use a linkage criterion to determine the underperforming battery rack. The single linkage approach may utilize minimum distance criteria between data points to form clusters, where the single linkage may be used to determine a large deviation in the underperforming battery rack by identifying data points that exhibit significant separation from normal operational clusters.

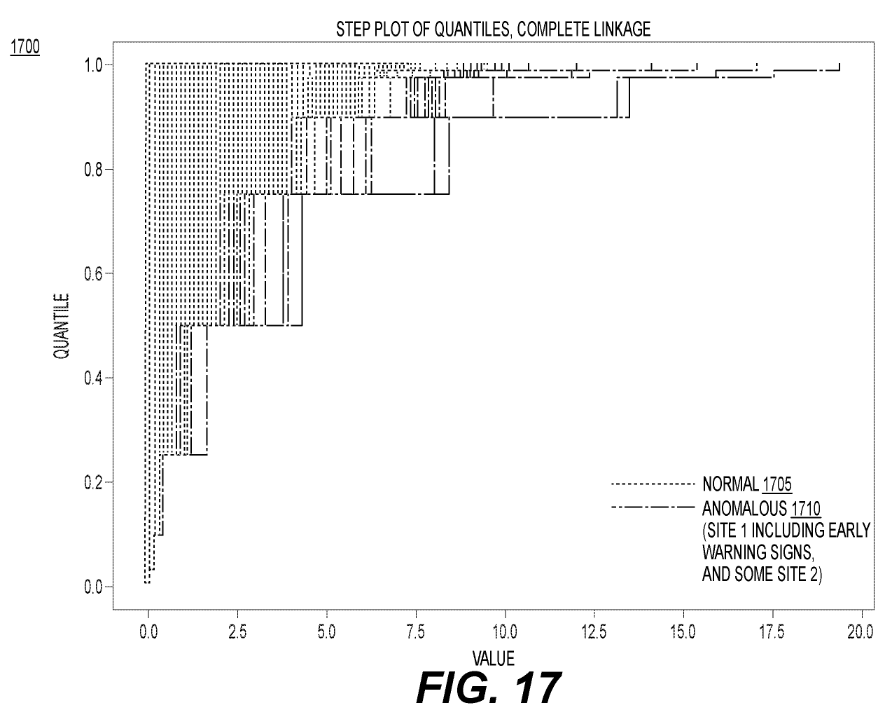

FIG. 17 depicts a complete linkage quantile graph showing step plots for complete linkage clustering analysis, according to one or more embodiments. With reference to FIG. 17, a complete linkage quantile graph 1700 may show a step plot of quantiles for complete linkage clustering analysis. The complete linkage quantile graph 1700 may display quantile values on the vertical axis ranging from 0.0 to 1.0, and rack current delta value measurements on the horizontal axis ranging from 0.0 to approximately 20.0. The complete linkage quantile graph 1700 may demonstrate how complete linkage clustering methodology may provide enhanced sensitivity for detecting gradual variations in battery rack performance compared to single linkage approaches.

The complete linkage quantile graph 1700 may include normal site data 1705, which may be represented by a dotted pattern filling the left portion of the graph and extending from lower quantile and value ranges. The normal site data 1705 may correspond to battery rack operational data that exhibits typical performance characteristics without significant anomalous conditions. The normal site data 1705 may demonstrate how complete linkage clustering may group normal operational patterns together using maximum distance criteria, which may provide more stringent clustering requirements compared to single linkage methodology.

The complete linkage quantile graph 1700 may also include anomalous site data 1710, which may be represented by a dash-dot line pattern that appears at higher value ranges. The anomalous site data 1710 may indicate data points identified as anomalous conditions that may include early warning signs and other performance deviations detected across multiple battery installation sites. The complete linkage approach may be used to determine an early warning sign in the underperforming battery rack by identifying smaller gradual deviations that may not be detected using single linkage criteria, thereby providing enhanced capability for proactive maintenance interventions.

The machine learning model may include an agglomerative hierarchical clustering model that may form a specified number of clusters by clustering points based on linkage criteria. The agglomerative hierarchical clustering model may utilize complete linkage using maximum distance criteria, which may enable detection of smaller gradual deviations compared to single linkage approaches. The linkage criterion may be a single linkage or a complete linkage, where the selection of linkage criteria may influence the sensitivity and specificity of anomaly detection for different types of performance degradation patterns in battery energy storage systems.

The method for controlling a battery energy storage system may further include specifying a number of clusters for the trained machine learning model and not specifying a number of free parameters for the trained machine learning model. The agglomerative hierarchical clustering approach may provide parameter-free clustering capabilities by requiring only the specification of the desired number of clusters without requiring adjustment of distance parameters or other free parameters that may need manual tuning. This parameter-free characteristic may simplify the deployment and operation of the trained machine learning model across different battery installation sites and operating conditions.

The clustering model may use Ward linkage or Average linkage criteria in addition to single linkage and complete linkage options. Ward linkage may minimize the increase in within-cluster variance when merging clusters, potentially providing enhanced clustering performance for battery rack current data that exhibits complex distribution patterns. Average linkage may use the average distance between all pairs of points in different clusters as the linkage criterion, which may provide intermediate sensitivity between single linkage and complete linkage approaches for detecting various types of performance anomalies in battery energy storage systems.

The machine learning model may include one or more of a density-based clustering model, a Gaussian mixture model, or a K-means model as alternative clustering approaches. The machine learning model may include DBSCAN density-based clustering as an alternative clustering method that may identify clusters based on density criteria rather than distance-based linkage criteria. DBSCAN may provide advantages for detecting anomalous battery rack behavior that forms dense clusters separated from normal operational patterns, though DBSCAN may require proper selection and tuning of adjustable distance parameters that may increase implementation complexity compared to parameter-free agglomerative hierarchical clustering approaches.

The Gaussian mixture model may cluster data points into a specified number of Gaussian clusters, which may be suitable for battery rack current data that exhibits approximately Gaussian distribution patterns. The K-means clustering approach may be more suitable for spherical clusters and may provide computational efficiency advantages for large datasets, though K-means may have limitations when applied to battery rack current data that exhibits non-spherical cluster geometries or varying cluster densities across different operational conditions and geographic sites.

The agglomerative hierarchical clustering model may provide enhanced flexibility for anomaly detection in battery energy storage systems by enabling selection of appropriate linkage criteria based on the specific characteristics of the anomalous conditions being detected. Single linkage may be optimal for identifying clearly separated anomalous conditions with large deviations from normal patterns, while complete linkage may be preferred for detecting subtle early warning signs that require more sensitive clustering criteria. The combination of multiple linkage approaches may enable comprehensive anomaly detection coverage that addresses both immediate performance issues requiring urgent intervention and gradual performance degradation that may benefit from proactive maintenance scheduling.

The method for controlling a battery energy storage system may include initiating an action based on the rack deviation, where the action may include one or more of generating a notification based on the underperforming battery rack and the rack deviation, automatically deactivating the underperforming battery rack, or discharging the underperforming battery rack. The system may determine appropriate responses based on anomaly severity levels and rack performance characteristics derived from the reconstruction loss analysis and anomaly score calculations performed by the trained machine learning model.

The system may generate a notification based on the underperforming battery rack and the rack deviation when the trained machine learning model identifies anomalous conditions that exceed predetermined performance thresholds. The notification may include detailed diagnostic information about the specific battery rack exhibiting anomalous behavior, including the magnitude of the rack deviation, the time period during which the anomalous condition was detected, and the confidence level of the anomaly detection based on the reconstruction loss or anomaly score values. The notification may be transmitted to maintenance personnel, system operators, or automated maintenance scheduling systems to enable appropriate response actions.

The notification generation process may be customized based on the severity level of the detected anomaly, where different notification protocols may be implemented for early warning conditions versus clearly anomalous conditions requiring immediate attention. For early warning conditions with moderate reconstruction loss values, the notification may include trend analysis information, recommended monitoring intervals, and suggested maintenance scheduling windows that allow for proactive intervention during planned maintenance periods. For severe anomalous conditions with high reconstruction loss values indicating potential intermittent loose connections, the notification may include immediate alert messages with detailed diagnostic data and recommended emergency response procedures.

The system may automatically deactivate the underperforming battery rack when the rack deviation exceeds critical performance thresholds that may indicate safety risks or potential cascading failures across multiple battery racks. The automatic deactivation process may involve isolating the underperforming battery rack from the electrical connections to other battery racks within the battery energy storage system, preventing the anomalous conditions from affecting the performance of adjacent battery racks or compromising overall system stability. The automatic deactivation may be implemented through electronic switching mechanisms or relay systems that can rapidly disconnect the underperforming battery rack from the main power distribution network.

The automatic deactivation decision may be based on multiple factors including the magnitude of the rack deviation, the duration of the anomalous condition, the rate of performance degradation, and the potential impact on overall system performance. The system may implement graduated deactivation protocols where minor anomalous conditions may result in partial deactivation or reduced operational capacity, while severe anomalous conditions may trigger complete isolation of the underperforming battery rack. The automatic deactivation process may include safety interlocks and confirmation mechanisms to prevent inadvertent deactivation due to transient anomalous conditions or false positive detections.

The system may discharge the underperforming battery rack as a controlled response action when the rack deviation indicates conditions that may benefit from controlled energy removal before maintenance interventions. The discharging process may involve systematically reducing the stored energy in the underperforming battery rack through controlled current draw or connection to discharge resistors, bringing the battery rack to a safe energy state for maintenance activities. The controlled discharge may prevent potential safety hazards during maintenance operations and may reduce the risk of thermal events or electrical arcing that could occur if maintenance were performed on a fully charged battery rack with intermittent loose connections.

The discharge operation may be implemented through programmable discharge circuits that can control the discharge rate and monitor the discharge process to ensure safe energy removal from the underperforming battery rack. The discharge rate may be determined based on the specific characteristics of the detected anomaly, the thermal conditions of the battery rack, and the urgency of the required maintenance intervention. Rapid discharge may be implemented for emergency conditions requiring immediate maintenance access, while gradual discharge may be used for planned maintenance activities where time constraints are less critical.

The system may implement decision logic that determines the appropriate combination of actions based on the specific characteristics of the detected rack deviation and the operational context of the battery energy storage system. Multiple actions may be initiated simultaneously, such as generating notifications while also beginning controlled discharge procedures, or the actions may be implemented in sequence based on the progression of the anomalous condition. The decision logic may consider factors such as the availability of backup power capacity, the criticality of the electrical load being served by the battery energy storage system, and the availability of maintenance personnel to respond to the detected anomaly.

The action selection process may utilize machine learning algorithms to optimize response strategies based on historical data about the effectiveness of different response actions for various types of anomalous conditions. The system may learn from previous anomaly detection events and their outcomes to improve the accuracy of action selection for future anomalous conditions. The machine learning-based action selection may consider the success rates of different response strategies, the time required for various maintenance interventions, and the impact of different actions on overall system availability and performance.

The system may provide feedback mechanisms that allow operators to override or modify the automatically selected actions based on operational requirements or site-specific considerations. The feedback mechanisms may include manual override controls that enable operators to prevent automatic deactivation when system availability requirements take precedence over anomaly response, or to accelerate discharge procedures when maintenance scheduling requires rapid intervention. The operator feedback may be incorporated into the machine learning algorithms to improve future action selection decisions based on site-specific operational preferences and constraints.

The battery energy storage system may include one or more processors and one or more memories storing instructions that, when executed by the one or more processors, cause the one or more processors to perform operations including initiating an action based on the rack deviation. The system implementation may utilize distributed processing capabilities where different processors may handle anomaly detection, action selection, and action execution functions to ensure reliable and timely response to detected anomalous conditions. The distributed processing architecture may provide redundancy and fault tolerance to prevent system failures from compromising the anomaly response capabilities.

The non-transitory computer readable medium for controlling a battery energy storage system may store instructions that, when executed by one or more processors, cause the one or more processors to perform operations including initiating an action based on the rack deviation. The stored instructions may include algorithms for evaluating rack deviation severity, selecting appropriate response actions, coordinating multiple simultaneous actions, and monitoring the effectiveness of implemented response strategies. The computer readable medium may also store historical data about previous anomaly events and response outcomes to support machine learning-based optimization of future response actions.

In summary, one or more embodiments may provide several advantages and improvements over existing battery energy storage system monitoring technologies. The machine learning-based anomaly detection approach may enhance the identification of intermittent loose connections through automated analysis of current deviations, enabling early detection before complete failure occurs. The semi-supervised and unsupervised learning methodologies may reduce the dependency on labeled anomalous data while providing robust detection capabilities across diverse operational conditions and geographic sites. The multi-modal detection system utilizing autoencoder, variational autoencoder, and GANomaly architectures may offer graduated anomaly scoring that may distinguish between normal operation, early warning conditions, and severe anomalous conditions requiring immediate intervention. The agglomerative hierarchical clustering approach may provide parameter-free anomaly detection with selectable linkage criteria to optimize sensitivity for different types of performance degradation patterns. The automated response system may enable intelligent action selection including notification generation, controlled deactivation, and safe discharge procedures based on anomaly severity and operational context. The distributed processing architecture may ensure reliable and timely response to detected anomalous conditions while providing redundancy and fault tolerance. These improvements may collectively result in enhanced system reliability, reduced maintenance costs, improved safety, and extended operational lifetime for battery energy storage systems through proactive identification and management of performance anomalies.

It should be understood that the foregoing description is intended to illustrate, and not to limit, the scope of the present disclosure. Other embodiments will be apparent to those skilled in the art in view of this description. For example, while certain embodiments are described with respect to lithium-ion batteries, the disclosed structures, materials, and methods may be applied to next-generation energy storage devices including, without limitation, solid-state batteries employing solid electrolytes, lithium-metal or lithium-sulfur chemistries, sodium-ion systems, multivalent-ion systems (e.g., magnesium, calcium, aluminum), zinc-based or redox flow batteries, and metal-air cells. Still further embodiments may include architectures employing silicon-based anodes, cobalt-free cathodes, or advanced electrolyte formulations. In some cases, anode-less designs, in which active material is plated during charge, or separator-free designs, in which the electrolyte provides ionic conduction and electronic insulation without a discrete separator, may be implemented. The present disclosure also contemplates hybridized devices combining electrochemical cells with supercapacitors, as well as integration into applications such as electric or hybrid vehicles, stationary energy storage systems, aerospace platforms, and portable electronics. Accordingly, the scope of the present invention should be determined not by the particular embodiments described, but by reference to the appended claims and their equivalents.

The present disclosure further relates to the following aspects.

Example 1. A method for controlling a battery energy storage system, the method comprising: receiving a current delta for each battery rack of a plurality of battery racks, wherein the current delta is a first difference in current between each battery rack and a mean or median current of the plurality of battery racks; determining, via a machine learning model, a first battery rack of the plurality of battery racks by: comparing the current delta for each battery rack of the plurality of battery racks to a performance threshold, and based on the comparing, determining the first battery rack of the plurality of battery racks; determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and initiating an action based on the rack deviation, the action including one or more of: generating a notification based on the first battery rack and the rack deviation, deactivating the first battery rack, or discharging the first battery rack.

Example 2. The method of example 1, further comprising: determining an anomaly score scaled between 0 and 1 for the first battery rack based on the rack deviation for the first battery rack, and wherein the comparing the current delta for each battery rack of the plurality of battery racks to a performance threshold includes using a performance threshold of 0.2 to 0.4 for the scaled anomaly score.

Example 3. The method of example 2, further comprising: receiving temperature data associated with the first battery rack; and determining the anomaly score for the first battery rack based on the rack deviation for the first battery rack and the temperature data for the first battery rack.

Example 4. The method of example 3, further comprising: grouping the anomaly score for the first battery rack into one of a first group and a second group, based on the rack deviation for the first battery rack, wherein rack deviations of the first group are less than rack deviations of the second group; and generating the notification further includes generating the notification based on the grouping.

Example 5. The method of example 1, wherein the machine learning model includes a trained machine learning model that has been trained to determine the first battery rack based on current data, and wherein the trained machine learning model includes one or more of an autoencoder model, a variational autoencoder model, or a GANomaly model, and the trained machine learning model has been trained with non-anomalous data.

Example 6. The method of example 5, wherein: the trained machine learning model includes a semi-supervised machine learning algorithm trained with normal non-anomalous data, and the trained machine learning model produces an output with low reconstruction loss for non-anomalous data, and produces an output with high reconstruction loss for anomalous data to determine the first battery rack.

Example 7. The method of example 1, wherein: the machine learning model includes an unsupervised machine learning algorithm, and the machine learning model is configured to cluster the current data into clustered data based on reducing within-cluster distance and separating different clusters, and applies a linkage criterion to determine the first battery rack.

Example 8. The method of example 7, wherein the unsupervised machine learning algorithm includes an agglomerative hierarchical clustering model.

Example 9. The method of example 7, wherein the linkage is a single linkage or a complete linkage.

Example 10. The method of example 9, wherein the single linkage is used to determine a large deviation in the first battery rack, and the complete linkage is used to determine an early warning sign in the first battery rack.

Example 11. The method of example 7, further comprising: specifying a number of clusters for the unsupervised machine learning algorithm and not specifying a number of free parameters for the unsupervised machine learning algorithm.

Example 12. The method of example 7, wherein the unsupervised machine learning algorithm includes one or more of a density-based clustering model, a Gaussian mixture model, or a K-means model.

Example 13. The method of example 1, wherein the machine learning model includes an encoder and a decoder.

Example 14. The method of example 1, wherein the current data includes a time series of the current data as a data set of normalized values or a data set of absolute values.

Example 15. The method of example 1, wherein the plurality of battery racks are located at different geographic sites, and wherein the plurality of battery racks have one or more different site configurations and one or more different operating conditions.

Example 16. A non-transitory computer readable medium for controlling a battery energy storage system, the non-transitory computer readable medium storing instructions that, when executed by one or more processors, cause the one or more processors to perform operations comprising: receiving a current delta for each battery rack of a plurality of battery racks, wherein the current delta is a first difference in current between each battery rack and a mean or median current of the plurality of battery racks; determining, via a machine learning model, a first battery rack of the plurality of battery racks by: comparing the current delta for each battery rack of the plurality of battery racks to a performance threshold, and based on the comparing, determining the first battery rack of the plurality of battery racks; determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and initiating an action based on the rack deviation, the action including one or more of: generating a notification based on the first battery rack and the rack deviation, deactivating the first battery rack, or discharging the first battery rack.

Example 17. The non-transitory computer readable medium of example 16, wherein the machine learning model includes one or more of a semi-supervised machine learning model or an unsupervised machine learning model.

Example 18. A battery energy storage system comprising: one or more processors; and one or more memories storing instructions that, when executed by the one or more processors, cause the one or more processors to perform operations including: receiving a current delta for each battery rack of a plurality of battery racks, wherein the current delta is a first difference in current between each battery rack and a mean or median current of the plurality of battery racks; determining, via a machine learning model, a first battery rack of the plurality of battery racks by: comparing the current delta for each battery rack of the plurality of battery racks to a performance threshold, wherein the performance threshold is a scaled anomaly score from 0.2 to 0.4, and based on the comparing, determining the first battery rack of the plurality of battery racks; determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and initiating an action based on the rack deviation, the action including one or more of: generating a notification based on the first battery rack and the rack deviation, deactivating the first battery rack, or discharging the first battery rack.

Example 19. The battery energy storage system of example 18, wherein the machine learning model includes one or more of a semi-supervised machine learning model or an unsupervised machine learning model.

Example 20. The battery energy storage system of example 18, further including: one or more of the plurality of battery racks; and a housing for the one or more of the plurality of battery racks.

Example 21. The method of example 1, wherein the machine learning model uses z-scores to normalize the current data, wherein the z-scores are calculated by subtracting a mean and dividing by a standard deviation.

Example 22. The method of example 1, wherein the machine learning model uses a modified z-score using a median and median absolute deviation instead of a mean and standard deviation.

Example 23. The method of example 1, wherein when a standard deviation of the current data is smaller than a preset threshold, corresponding z-scores are set to zero.

Example 24. The method of example 1, wherein the preset threshold is a precision of current measurement or a fraction of a mean current.

Example 25. The method of example 1, wherein the machine learning model includes a beta-variational autoencoder that applies a weight term beta to a KL divergence in a loss function.

Example 26. The method of example 1, wherein the machine learning model utilizes a total loss function comprising a sum of reconstruction loss and KL divergence between a prior distribution and a posterior distribution learned by an encoder.

Example 27. The method of example 1, wherein the machine learning model includes a GANomaly architecture comprising a generator with an encoder-decoder-encoder structure and a discriminator.

Example 28. The method of example 1, wherein the machine learning model calculates an encoder loss based on a difference between a first encoded representation and a second encoded representation of reconstructed data.

Example 29. The method of example 1, wherein the machine learning model calculates a contextual loss based on a difference between input data and reconstructed output data.

Example 30. The method of example 1, wherein the machine learning model calculates an adversarial loss based on a difference between discriminator responses to real data and reconstructed data.

Example 31. The method of example 1, wherein the machine learning model includes a convolutional neural network architecture for processing time series current data.

Example 32. The method of example 1, wherein the machine learning model includes a deep neural network architecture for processing statistical features derived from current delta measurements.

Example 33. The method of example 1, further comprising identifying early warning signs based on medium reconstruction loss values that fall between low reconstruction loss of normal data and high reconstruction loss of anomalous data.

Example 34. The method of example 1, wherein the action of deactivating the first battery rack includes isolating the first battery rack from electrical connections to other battery racks within the battery energy storage system.

Example 35. The method of example 1, wherein the action of discharging the first battery rack includes systematically reducing stored energy in the first battery rack through controlled current draw.

Example 36. The method of example 1, wherein the notification includes diagnostic information comprising a magnitude of the rack deviation, a time period during which an anomalous condition was detected, and a confidence level of anomaly detection.

Example 37. The method of example 1, wherein features used by the machine learning model include statistical metrics of a distribution of underperforming rack current deltas, including quantiles, standard deviation, interquartile range, and spreads.

Example 38. The method of example 1, wherein the machine learning model uses Ward linkage or Average linkage criteria for clustering.

Example 39. The method of example 1, wherein the machine learning model is applied to voltage time series data in addition to the current data for anomaly detection.

Example 40. The method of example 1, wherein the machine learning model is applied to temperature time series data in addition to the current data for anomaly detection.

Example 41. The non-transitory computer readable medium of example 16, wherein the machine learning model uses z-scores to normalize the current data by subtracting a mean and dividing by a standard deviation.

Example 42. The non-transitory computer readable medium of example 16, wherein the machine learning model includes a beta-variational autoencoder that applies a weight term beta to a KL divergence in a loss function.

Example 43. The non-transitory computer readable medium of example 16, wherein the machine learning model includes a GANomaly architecture comprising a generator with an encoder-decoder-encoder structure and a discriminator.

Example 44. The non-transitory computer readable medium of example 16, wherein the operations further include identifying early warning signs based on medium reconstruction loss values that fall between low reconstruction loss of normal data and high reconstruction loss of anomalous data.

Example 45. The non-transitory computer readable medium of example 16, wherein features used by the machine learning model include statistical metrics of a distribution of underperforming rack current deltas, including quantiles, standard deviation, interquartile range, and spreads.

Example 46. The non-transitory computer readable medium of example 16, wherein the action of deactivating the first battery rack includes isolating the first battery rack from electrical connections to other battery racks within the battery energy storage system.

Example 47. The battery energy storage system of example 18, wherein the machine learning model uses z-scores to normalize the current data by subtracting a mean and dividing by a standard deviation.

Example 48. The battery energy storage system of example 18, wherein the machine learning model includes a beta-variational autoencoder that applies a weight term beta to a KL divergence in a loss function.

Example 49. The battery energy storage system of example 18, wherein the machine learning model includes a GANomaly architecture comprising a generator with an encoder-decoder-encoder structure and a discriminator.

Example 50. The battery energy storage system of example 18, wherein the operations further include identifying early warning signs based on medium reconstruction loss values that fall between low reconstruction loss of normal data and high reconstruction loss of anomalous data.

Example 51. The method of example 1, wherein method further includes example 17.

Example 52. The method of example 1, wherein method further includes any of examples 19 to 20.

Example 53. The method of example 1, wherein method further includes any of examples 41 to 50.

Example 54. The non-transitory computer readable medium of example 16, further including any of examples 2 to 15.

Example 55. The non-transitory computer readable medium of example 16, further including any of examples 19 to 40.

Example 56. The non-transitory computer readable medium of example 16, further including any of examples 47 to 50.

Example 58. The battery energy storage system of example 18, further including example 17.

Example 57. The battery energy storage system of example 18, further including any of examples 2 to 15.

Example 59. The battery energy storage system of example 18, further including any of examples 21 to 46.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for controlling a battery energy storage system, the method comprising:
receiving a current delta for each battery rack of a plurality of battery racks, wherein the current delta is a first difference in current between each battery rack and a mean or median current of the plurality of battery racks;
determining, via a machine learning model, a first battery rack of the plurality of battery racks by:
comparing the current delta for each battery rack of the plurality of battery racks to a performance threshold, and
based on the comparing, determining the first battery rack of the plurality of battery racks;
determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and
initiating an action based on the rack deviation, the action including one or more of:
generating a notification based on the first battery rack and the rack deviation,
deactivating the first battery rack, or
discharging the first battery rack.

2. The method of claim 1, further comprising:
determining an anomaly score scaled between 0 and 1 for the first battery rack based on the rack deviation for the first battery rack, and wherein the comparing the current delta for each battery rack of the plurality of battery racks to a performance threshold includes using a performance threshold of 0.2 to 0.4 for the scaled anomaly score.

3. The method of claim 2, further comprising:
receiving temperature data associated with the first battery rack; and
determining the anomaly score for the first battery rack based on the rack deviation for the first battery rack and the temperature data for the first battery rack.

4. The method of claim 3, further comprising:
grouping the anomaly score for the first battery rack into one of a first group and a second group, based on the rack deviation for the first battery rack, wherein rack deviations of the first group are less than rack deviations of the second group; and
generating the notification further includes generating the notification based on the grouping.

5. The method of claim 1, wherein the machine learning model includes a trained machine learning model that has been trained to determine the first battery rack based on current data, and wherein the trained machine learning model includes one or more of an autoencoder model, a variational autoencoder model, or a GANomaly model, and the trained machine learning model has been trained with non-anomalous data.

6. The method of claim 5, wherein:
the trained machine learning model includes a semi-supervised machine learning algorithm trained with normal non-anomalous data, and
the trained machine learning model produces an output with low reconstruction loss for non-anomalous data, and produces an output with high reconstruction loss for anomalous data to determine the first battery rack.

7. The method of claim 1, wherein:
the machine learning model includes an unsupervised machine learning algorithm, and
the machine learning model is configured to cluster the current data into clustered data based on reducing within-cluster distance and separating different clusters, and applies a linkage criterion to determine the first battery rack.

8. The method of claim 7, wherein the unsupervised machine learning algorithm includes an agglomerative hierarchical clustering model.

9. The method of claim 7, wherein the linkage is a single linkage or a complete linkage.

10. The method of claim 9, wherein the single linkage is used to determine a large deviation in the first battery rack, and the complete linkage is used to determine an early warning sign in the first battery rack.

11. The method of claim 7, further comprising:
specifying a number of clusters for the unsupervised machine learning algorithm and not specifying a number of free parameters for the unsupervised machine learning algorithm.

12. The method of claim 7, wherein the unsupervised machine learning algorithm includes one or more of a density-based clustering model, a Gaussian mixture model, or a K-means model.

13. The method of claim 1, wherein the machine learning model includes an encoder and a decoder.

14. The method of claim 1, wherein the current data includes a time series of the current data as a data set of normalized values or a data set of absolute values.

15. The method of claim 1, wherein the plurality of battery racks are located at different geographic sites, and wherein the plurality of battery racks have one or more different site configurations and one or more different operating conditions.

16. A non-transitory computer readable medium for controlling a battery energy storage system, the non-transitory computer readable medium storing instructions that, when executed by one or more processors, cause the one or more processors to perform operations comprising:
receiving a current delta for each battery rack of a plurality of battery racks, wherein the current delta is a first difference in current between each battery rack and a mean or median current of the plurality of battery racks;
determining, via a machine learning model, a first battery rack of the plurality of battery racks by:
comparing the current delta for each battery rack of the plurality of battery racks to a performance threshold, and
based on the comparing, determining the first battery rack of the plurality of battery racks;
determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and
initiating an action based on the rack deviation, the action including one or more of:
generating a notification based on the first battery rack and the rack deviation,
deactivating the first battery rack, or
discharging the first battery rack.

17. The non-transitory computer readable medium of claim 16, wherein the machine learning model includes one or more of a semi-supervised machine learning model or an unsupervised machine learning model.

18. A battery energy storage system comprising:
one or more processors; and
one or more memories storing instructions that, when executed by the one or more processors, cause the one or more processors to perform operations including:
receiving a current delta for each battery rack of a plurality of battery racks, wherein the current delta is a first difference in current between each battery rack and a mean or median current of the plurality of battery racks;
determining, via a machine learning model, a first battery rack of the plurality of battery racks by:
comparing the current delta for each battery rack of the plurality of battery racks to a performance threshold, wherein the performance threshold is a scaled anomaly score from 0.2 to 0.4, and
based on the comparing, determining the first battery rack of the plurality of battery racks;
determining, via the machine learning model, a rack deviation by determining a second difference between the mean or median current of each of the plurality of battery racks and a current of the first battery rack over a period of time, wherein the period of time includes ten to thirty second intervals over 24 hours, and wherein the machine learning model determines the first battery rack based on current data; and
initiating an action based on the rack deviation, the action including one or more of:
generating a notification based on the first battery rack and the rack deviation,
deactivating the first battery rack, or
discharging the first battery rack.

19. The battery energy storage system of claim 18, wherein the machine learning model includes one or more of a semi-supervised machine learning model or an unsupervised machine learning model.

20. The battery energy storage system of claim 18, further including:
one or more of the plurality of battery racks; and
a housing for the one or more of the plurality of battery racks.
